(19) United States
(12) Patent Application Publication
(10) Pub. No.: US 2021/0024766 A1
(43) Pub. Date: Jan. 28, 2021

(54) SILVER PASTE COMPOSITION FOR CONFIGURABLE SINTERED INTERCONNECT AND ASSOCIATED METHOD OF PREPARATION

(71) Applicant: EOPLEX LIMITED, Hong Kong (CN)

(72) Inventors: Joe CHOU, San Mateo, CA (US); Chungdee PONG, Los Altos, CA (US); Roslan Bin AFFANDI, Singapore (SG)

(21) Appl. No.: 16/942,796

(22) PCT Filed: Jan. 31, 2018
(86) PCT No.: PCT/IB2018/050579

§ 371 Date: Jul. 30, 2020

(51) Int. Cl. C09D 11/52; C09D 11/10; H01L 23/495; H01L 23/498; H01L 23/00; C22C 5/06

(52) U.S. Cl. CPC C09D 11/52; C09D 11/10; H01L 23/49579; H01L 2224/85439; H01L 24/83; C22C 5/06; H01L 2224/8384; H01L 23/49883

(57) ABSTRACT

A silver paste composition for screen and/or 3D printing of interconnects of an integrated circuit chip on a metal oxide ink coated stainless steel substrate carrier comprising a mixture of two or more distinct range of sizes of electrically conductive silver particles, a resin in an amount from 0.05 to 10 wt. % of the silver paste composition, a solvent in an amount from 1 to 25 wt. % of the silver paste composition, such that the silver paste composition has silver particles containing calcium content of less than 20 ppm and a viscosity of 10 to 400 Pa·s at a shear rate of 10 sec⁻¹ at 25° C.

### TECHNICAL FIELD

This disclosure relates to a silver paste for use with an integrated circuit chip for providing an effective interconnection of the integrated circuit chip in an electrical system. More particularly, this disclosure relates to a silver paste for use as an interconnect on stainless steel lead frames and/or other lead carriers which are manufactured as an array of multiple package sites for use on electronic system boards such as a printed circuit board.

### BACKGROUND

The growing need for smaller, more cost efficient and higher performance semiconductor packages are fueled by significant growth in the mobile, wearable and IOT device spaces. Existing packages (e.g., QFP, BGA, DCA) have a big footprint, thick packaging with special manufacturing requirements, and limited applicability and are expensive.

To mitigate the above shortcomings, Applicant utilizes a Configurable Sintered Interconnect (CSI™) technology and process which uses screen and/or 3D-printing technology to print package components onto a temporary metal oxide ink coated stainless steel carrier which is removed after assembly and testing. Such a CSI™ semiconductor packaging technology provides cost, size, and performance efficiencies to customers including a miniature footprint, excellent electric and thermal performances, EMI shielding capability, ability to incorporate passive devices, adaptable and flexibility to various QFP, GBA, QFN and advanced SiP packaging types with potential for stacking.

The old/standard QFN lead frames with tie bars having poor signal integrity, material wastage and limited size/lead count limitations are replaced with the CSI™ platform comprising 3D printed package components, removable stainless steel carrier for configuring die and terminal pads for interconnects with a lower cost, higher performance, high I/O densities coupled with a smaller footprint and highly adaptable to fit many packaging types.

The current invention relates to a silver paste composition for use as an interconnect on the metal oxide ink coated stainless steel carrier or lead frames which may be manufactured as an array of multiple package sites for use on electronic system boards such as a printed circuit board. The adhesion between the sintered silver paste and metal oxide ink coated stainless steel substrate carrier is a critical feature for downstream die attach, wire bond, polymer compress molding, soldering and stainless steel substrate carrier removal processes.

### SUMMARY

In various embodiments of the present disclosure, a silver paste composition is disclosed for screen and/or 3D printing of interconnects of an integrated circuit chip on a metal oxide ink coated stainless steel substrate carrier comprising: a mixture of two or more distinct range of sizes of electrically conductive silver particles; a resin in an amount from 0.05 to 10 wt. % of the weight of the silver paste composition; a solvent in an amount from 1 to 25 wt. % of the weight of the silver paste composition, wherein the conductive silver particles are imbedded with a calcium content of less than 20 ppm, and wherein the silver paste composition has a viscosity of 10 to 400 Pa·s at a shear rate of 10 sec⁻¹ at 25° C.

In one aspect of the disclosure, the mixture of two or more distinct range of sizes of electrically conductive silver particles comprises: a combination of two or more multi-micron-sized silver particles, wherein smaller micron-sized particles are in the range of 3 to 8 μm with a particle size distribution of D50, and bigger micron-sized particles are in the range of 8 to 20 μm with a particle size distribution of D90; and wherein the wt. ratio of the bigger micron-sized particles to the smaller micron-sized particles is approximately 3:1, and wherein the multi-micron-sized silver particles are greater than 50 wt. % of the silver paste composition.

In another aspect of the disclosure, the mixture of two or more distinct range of sizes of electrically conductive silver particles further comprises: a combination of two or more multi-micron-sized silver particles, wherein smaller micron-sized particles are in the range of 3 to 8 μm with a particle size distribution of D50, and bigger micron-sized particles are in the range of 8 to 20 μm with a particle size distribution of D90; and wherein the wt. ratio of the bigger micron-sized particles to the smaller micron-sized particles is approximately 4:1, and wherein the multi-micron-sized silver particles are greater than 50 wt. % of the silver paste composition; and one or more multi-nano-sized silver particles in the range of 10-150 nm, wherein the weight ratio of the multi-micron-sized silver particles to the multi-nano-sized silver particles is 34:1, and wherein the multi-nano-sized silver particles is from 1 to 10 wt. % of the silver paste composition.

In another aspect of the disclosure, the metal oxide ink is selected from among nickel oxide, titanium oxide, and calcium oxide.

In another aspect of the disclosure, the electrically conductive silver particles have a shape selected from among cubes, flakes, granules, cylinders, rings, rods, needles, prisms, disks, fibers, pyramids, spheres, spheroids, prolate spheroids, oblate spheroids, ellipsoids, ovoids and random non-geometric shapes.

In another aspect of the disclosure, the multi-micron-sized silver particles have a tapped density of 3.6 g/cc or higher and the multi-nano-sized silver particles have a tapped density of 2.4 g/cc or higher.

In another aspect of the disclosure, the resin is selected from among synthetic or natural resins, such as ethyl cellulose resins, rosin ester resins, acrylic resins, bisphenol resin, phenol resin, polyester, acrylic resin, coumarone resin, terpene resin, terpene phenol resin, styrene resin, xylene resin, polyvinyl alcohol and alkyd resin. The ethyl cellulose resin may further have a molecular weight of 8,000 to 50,000 g/mole.

In another aspect of the disclosure, the silver paste composition further comprises a dispersant in an amount from 0.01 to 7 wt. % of the silver paste composition. The dispersant is selected from among copolymers with acidic groups, such as the BYK® series, including phosphoric acid polyester (DIS PERBYK®111), BYK 9076, BYK 378, alkylolammonium salt of a polymer with acidic groups (DISPERBYK®180), structured acrylic copolymer (DISPERBYK®2008), structured acrylic copolymer with 2-butoxyethanol and 1-methoxy-2-propanol (DISPERBYK®2009), block copolymer with pigment affinic groups (DISPERBYK®2155), polycarboxylate ethers such as these in the Ethacryl series (Lyondell Chemical Company, Houston, Tex. USA), including Ethacryl 1030 and Ethacryl HF series (water-soluble polycarboxylate copolymers) such as Ethacryl M (polyether polycarboxylate sodium salt), Ethacryl 1000, Ethacryl G (water-soluble polycarboxylate copolymers containing polyalkylene oxide polymer), and Solsperser™ hyperdispersant series (Lubrizol, Wickliffe, Ohio USA) including Solsperse™ 35000, Solsperse™ 32000, Solsperse™ 20000, and Solsperse™ 33000 which are solid polyethylene-imine cores grafted with polyester hyper dispersant.

In another aspect of the disclosure, the solvent is selected from among acetophenone, benzyl alcohol, 2-butoxyethanol, 3-butoxy-butanol, butyl carbitol, y-butyrolactone, 1,2-dibutoxyethane, diethylene glycol monobutyl ether, dimethyl glutarate, dibasic ester mixture of dimethyl glutarate and dimethyl succinate, dipropylene glycol, dipropylene glycol monoethyl ether acetate, dipropylene glycol n-butyl ether, 2-(2-ethoxyethoxy)ethyl acetate, ethylene glycol, 2,4-heptanediol, hexylene glycol, methyl carbitol, N-methyl-pyrrolidone, 2,2,4-trimethyl-1,3-pentanediol di-isobutyrate (TXIB), 2,2,4-trimethyl-1,3-pentanediol monoisobutyrate (texanol), phenoxy ethanol, 1-phenoxy-2-propanol, phenyl carbitol, propylene glycol phenyl ether, terpineol, tetradecane, glycerol, tripropylene glycol n-butyl ether and mixtures of these solvents.

In another aspect of the disclosure, the silver paste composition further comprises an additive selected from among a leveling agent, a defoamer, and a wetting agent or a combination thereof. The additive may be present in an amount of less than 7 wt. % of the silver paste composition.

The present disclosure may further include a method of preparing a silver paste composition for screen and/or 3D printing of interconnects of an integrated circuit chip on a metal oxide ink coated stainless steel substrate carrier comprising: mixing two or more distinct range of sizes of electrically conductive silver particles; adding a resin in an amount from 0.05 to 10 wt. % of the silver paste composition; adding a solvent in an amount from 1 to 25 wt. % of the silver paste composition, wherein the conductive silver particles are imbedded with a calcium content of less than 20 ppm, and wherein the silver paste composition has a viscosity of 10 to 400 Pa·s at a shear rate of 10 sec⁻¹ at 25° C.

The mixture of two or more distinct range of sizes of electrically conductive silver particles may include a combination of two or more multi-micron-sized silver particles, wherein smaller micron-sized particles are in the range of 3 to 8 μm with a particle size distribution of D50, and bigger micron-sized particles are in the range of 8 to 20 μm with a particle size distribution of D90; and wherein the weight ratio of the bigger micron-sized particles to the smaller micron-sized particles is approximately 3:1, and wherein the multi-micron-sized silver particles are greater than 50 wt. % of the silver paste composition; or a combination of two or more multi-micron-sized silver particles, wherein a smaller micron-sized particles are in the range of 3 to 8 μm with a particle size distribution of D50, and a bigger micron-sized particles are in the range of 8 to 20 μm with a particle size distribution of D90; and wherein the wt. ratio of the bigger micron-sized particles to the smaller micron-sized particles is approximately 4:1, and wherein the multi-micron-sized silver particles are greater than 50 wt. % of the silver paste composition; and one or more multi-nano-sized silver particles in the range of 10-150 nm, wherein the wt. ratio between the multi-micron-sized silver particles to the multi-nano-sized silver particles is 34:1, and wherein the multi-nano-sized silver particles is from 1 to 10 wt. % of the silver paste composition.

The method may further include adding a dispersant in an amount from 0.01 to 7 wt. % of the silver paste composition.

The method may further include adding an additive selected from among a leveling agent, a defoamer, and a wetting agent or a combination thereof.

### Advantageous Effects

The sintered silver (at approximately 900° C.) serves as die attach pad (DAP) and wire bond interconnect sites (PAD), which provides excellent mechanical support for die, high electrical conductivity and high thermal release function between dice and soldered PCB or other devices.

The usage of a multi-micron-sized flake silver paste such as in Paste 1 provides excellent mechanical support for die, high electrical conductivity, very good thermal release property and enough adhesion between sintered silver features and coated stainless steel substrate carrier to enable the CSI™ packaging technology.

The addition of nano-sized silver particles such as in Paste 2 further provides significant adhesive strength improvement between sintered silver paste and coated stainless steel substrate carrier, reduces delamination of the sintered silver paste from the coated stainless steel substrate carrier during downstream processes and improves overall production yield as compared to the multi-micron-sized flake silver paste in Paste 1.

The high-volume screen and/or 3D printing technology and process are capable of printing features with the silver pastes as disclosed and allows for high-volume manufacturing of complex, multi-material devices that are difficult and expensive, if not impossible, to manufacture with conventional technology. Pastes 1 and 2 are disruptive in areas of semiconductor packaging and IOT/MEMS devices.

### DESCRIPTION OF THE DRAWINGS

FIGS. 1a-1b illustrate top and bottom of a die attach pad (DAP) and wire bond interconnect sites (PAD) silver paste composition features in accordance with an embodiment of the present disclosure;

FIG. 2 illustrates a CSI™ Packaging Process Flow in accordance with an embodiment of the present disclosure;

FIG. 3a illustrates an example of evaluating the DAP and PAD features' smallest surface area needed to meet minimum adhesion specification after the silver sintering process;

FIG. 3b illustrates a PAD surface area against adhesion/delamination test graph in accordance with an embodiment of the present disclosure;

FIG. 4 shows a graph illustrating rheology curves for Pastes 1 and 2;

FIG. 5 shows a graph illustrating rheology curves for Pastes 1 and 3;

FIG. 6 shows measured contact area (in percentage) on scanning electron microscope (SEM) pictures of the silver DAP contact to metal oxide ink coated stainless steel;

FIG. 7 shows yet other SEM pictures of the silver DAP contact surface area and morphology between metal oxide ink coated stainless steel and sintered silver layers;

FIGS. 8a-8b show the peel adhesion comparison by Penang, Malaysia, in automated high volume manufacturing process between the groups of control non-nano silver and nano silver DAP and PAD;

FIGS. 9a-9b show the sheer adhesion comparison by Penang, Malaysia, in automated high volume manufacturing process between the groups of control non-nano silver and nano silver DAP and PAD;

FIGS. 10a-10b show SEM pictures for good (low calcium content) and poor adhesion sample (high calcium content) for sintered silver to substrate peel off surface;

FIG. 11 shows sintered silver and special material contact stainless steel interfaces contact area comparison.

FIG. 12 shows the electrostatic spray deposition (EDS) analysis mapping for substrate and sintered silver contact for good adhesion sample with low calcium; and

FIGS. 13a-13b show the EDS analysis mapping for substrate and sintered silver contact for poor adhesion sample with high calcium.

### DETAILED DESCRIPTION

In the present disclosure, depiction of a given element or consideration or use of a particular element number in a particular figure or a reference thereto in corresponding descriptive material may encompass the same, an equivalent, or an analogous element or element number identified in another FIG. or descriptive material associated therewith. The use of “/” in a FIG. or associated text is understood to mean “and/or” unless otherwise indicated. The recitation of a particular numerical value or value range herein is understood to include or be a recitation of an approximate numerical value or value range, for instance, to within +/−10%, +/−5%, +/−2.5%, or +/−1% of a particular numerical value or value range under consideration.

The term silver paste and silver paste composition refers to the same unless stated otherwise in this disclosure. The terms multi-mircon and non-nano refers to the same unless stated otherwise in this disclosure.

In multiple embodiments, silver paste or silver paste compositions are disclosed for use in a CSI™ semiconductor packaging technology and process for screen and/or 3D printing on metal oxide ink coated stainless steel substrate carrier as die attach pad, wire bond interconnect sites using different design features to provide mechanical support, high electrical conductivity and good thermal release properties for packaging purposes. The silver paste composition is formulated to work with a metal oxide ink, such as nickel oxide, titanium oxide, and calcium oxide which is coated onto a stainless steel substrate carrier. Specifically, the silver paste compositions are designed to be screen and/or 3D printed features on a metal oxide ink coated stainless steel substrate carrier as die attach pad and wire bond interconnect sites after the silver paste compositions are sintered.

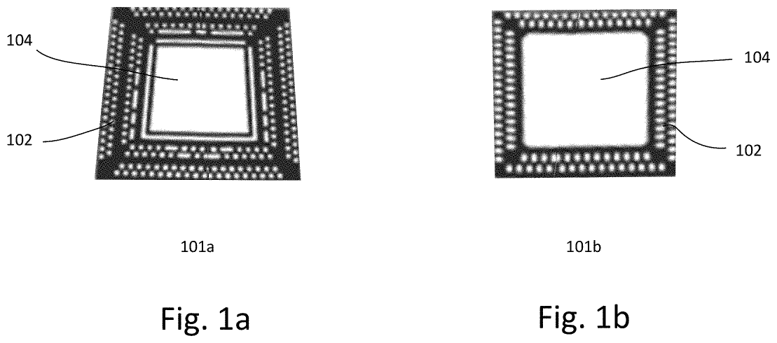

The CSI™ semiconductor packaging technology uses a high-volume screen and/or 3D printing technology and process and are capable of printing features with a silver paste that allows for high volume manufacturing of complex, multi-material devices that are difficult and expensive, if not impossible, to manufacture with conventional technology. Such a technology is disruptive in areas of semiconductor packaging and IOT/MEMs devices. FIGS. 1a-1b illustrates a die attach pad (DAP) 104 and wire bond interconnect sites (PAD) silver paste features 102 in accordance with embodiments 101a-b of the present disclosure.

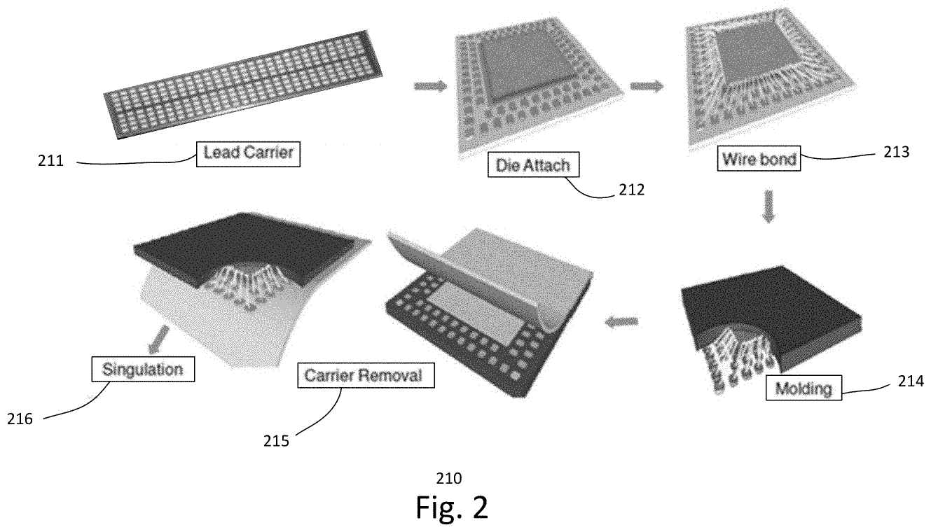

FIG. 2 illustrates an exemplary CSI™ packaging process flow 210 in accordance with an embodiment of the present disclosure. The CSI™ process starts with a stainless steel substrate carrier 211 spray-coated with a metal oxide ink and sintered between temperatures of 955° C. and 985° C. This is followed by a dry photoresist lamination, UV curing with different masks and acid etch processes to create the die attach pad (DAP) and wire bond interconnect sites (PAD) features for silver paste filling by using screen and/or 3D printing methods.

In an exemplary embodiment of this disclosure, new formulated silver pastes are screen and/or 3D printed onto the photoresist-patterned stainless steel substrate followed by drying through silver sintering processes at 150° C. and up to approximately 900° C. The samples are then subjected to a calendaring press process to reduce the height and to smoothen the surface of the substrate. The calendaring process is then followed by a special silver anti-corrosion surface coating, anti-epoxy bleeding coating, die attaching 212, wire bonding 213 and polymer compression molding processes 214 before peeling off the stainless steel substrate carrier 215, performing singulation 216 and soldering to the PCB or other devices.

After the calendaring process, a dye penetration test is used to evaluate the silver DAP features' potential leakage of die attach adhesive for the downstream die attach process. Die shear, die peel and tape tests are further utilized to evaluate the adhesion between the PAD and DAP sintered silver features and the coated stainless steel substrate carrier. Optical Gaging Products (OGP) and other tools are used to measure the DAP sintered silver features' heights and dimensions, and automated optical inspection tool is used to conduct high volume quality and delamination inspections. The delamination inspections are carried out after the calendaring, die attach, wire bond, polymer molding, stainless steel removal process, soldering and downstream reliability tests. The dye penetration test, die shear, die peel and tape tests are used as process control tools to gauge the production yield.

The adhesive strength between the sintered silver DAP and PAD features and metal oxide ink coated stainless steel substrate carrier is a critical specification of the packaging process. Any delamination between the sintered silver features and coated stainless steel substrate carrier will result in yield loss for the downstream calendaring, die attach, wire bond, polymer molding, soldering, substrate peeling processes and reliability tests.

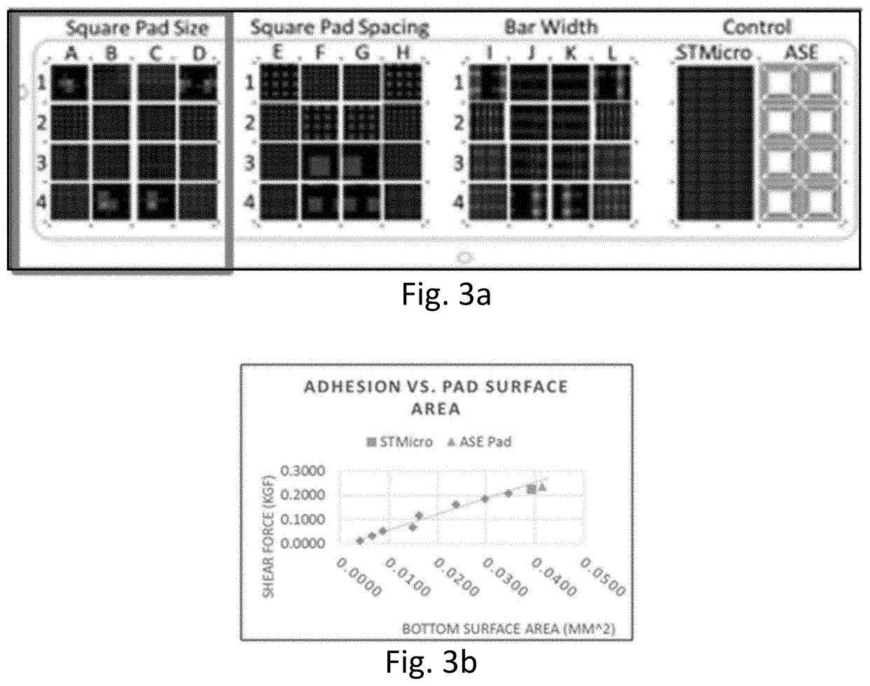

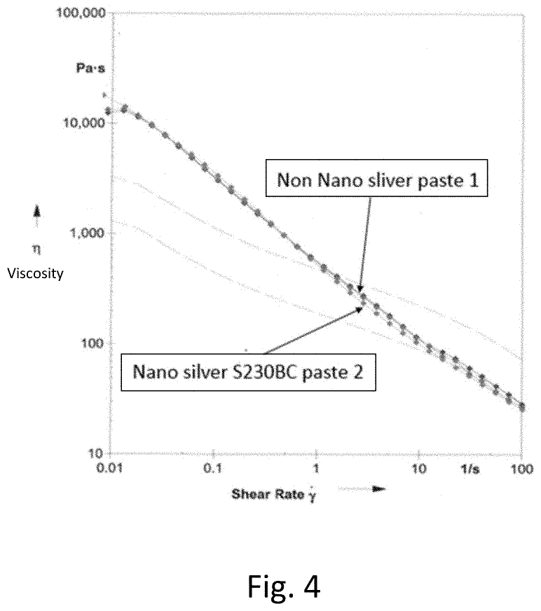

The interface between the metal oxide ink coated stainless steel substrate carrier and the sintered silver DAP and PAD features is expected to have many small gaps. The DAP and PAD surface areas and adhesion have to be within certain parameters, such as 150 gf for peel and 300 gf for shear, to eliminate the risk of sintered silver PAD and/or DAP delamination after the sintering, calendaring, die attach, wire bond, polymer molding, soldering and substrate peeling during downstream processes. An example of evaluating the DAP and PAD features' smallest surface area needed to meet minimum adhesion specification after the silver sintering process is shown in FIG. 3a.

The multi-micron-sized flake silver particles silver Paste 1 is shown to be adequate to enable the CSI™ packaging process with good adhesion. The adhesion between the printed and sintered silver features and metal oxide ink coated stainless steel substrate carrier allows the electrical conductivity and thermal release property to be adequate for enabling the CSI™ semiconductor packaging technology for passing downstream die attach, wire bond, polymer molding, soldering process and metal oxide ink coated stainless steel removal process. The nano-sized silver particles containing Pastes 2 and 3 are developed to enhance the adhesion between the sintered silver features and coated stainless substrate surface for yield improvement because the nano-sized silver particles in the paste composition are capable of penetrating into the gaps of the interface to increase bonding area and enhance interface adhesion.

The micron-sized flake silver particles (e.g., 5-10 μm) play a key role in preventing downstream die attach adhesive leakage into sintered silver DAP feature during die attach process and enable the sintered silver parts to pass the die penetration test used to evaluate the die attach adhesive leakage performance in Paste 1. With Pastes 2 and 3, silver paste using nano-sized particles (e.g., silver particles which are less than 150 nm (D50) in size, and preferably less than 10 nm in size) and multi-micron-sized/non-nano-sized flake silver particles in the paste composition, the adhesion between sintered silver features to special metal oxide ink coated stainless steel substrate carrier are significantly enhanced. This adhesion improvement significantly reduced silver to metal oxide ink coated stainless steel substrate carrier delamination and significantly improved the yield of semiconductor packaging technology.

### Rheology of Ink/Paste Compositions

In order for the silver paste to squeeze through a screen mesh, a low viscosity while printing is desired for the metal paste. However, in order to avoid spreading of the printed feature, a high viscosity after printing is desired for the silver paste. This leads to the requirement that screen printing pastes for high resolution must exhibit shear-thinning behavior, where the viscosity of the silver paste is high when the silver paste is at rest and is low when the silver paste is under shear.

The silver paste composition in an embodiment of this disclosure includes the mixture of silver particles that may determine the rheological properties of the silver paste. The viscosity of the silver paste composition may therefore be adjusted to fit the selected application. The silver paste composition is formulated to have a rheological property suitable for screen printing. Other rheological properties may be provided for 3D printing applications. In an exemplary embodiment, the silver particles are carried in a vehicle that contains appropriate organic solvents, resins, binders, dispersants, wetting agents, rheological modifiers, or a combination thereof. The conductive paste composition of the present application preferably includes optional rheological modifiers that yield unique rheological and printing properties. The rheology may be measured by a cone-plate rheometer.

### Description of the Silver Paste Compositions

In an exemplary embodiment, the silver paste composition includes a mixture of two or more distinct range of sizes of electrically conductive silver particles; a resin in an amount from 0.05 to 10 wt. % of the silver paste composition; a solvent in an amount from 1 to 25 wt. % of the silver paste composition, wherein the silver paste composition has a viscosity of 10 to 400 Pa·s at a shear rate of 10 sec¹ at 25° C.

Embodiments in accordance with the present disclosure include Paste 1 (non-nano) composition comprising:
(i) SF120 (D50 2 μm-D90 5 μm silver particles with a tapped density of 5 g/cc and a low calcium content of less than 10 ppm); and
(ii) SF125 (D50 4.7 μm-D90 9 μm silver particles with a tapped density of 5.8 g/cc and a low calcium content of less than 10 ppm).

Embodiments in accordance with the present disclosure include Paste 2 (nano) composition comprising:
(i) SF120 (D50 2 μm-D90 5 μm silver particles with a tapped density of 5 g/cc and a low calcium content of less than 10 ppm);
(ii) SF125 (D50 4.7 μm-D90 9 μm silver particles with a tapped density of 5.8 g/cc and a low calcium content of less than 10 ppm); and
(iii) S230 BC Nano silver (D50 50 nm with a tapped density of 2.4 g/cc and a low calcium content dispersed in butyl carbitol (70.29% silver)).

The weight ratio of the multi-micron-sized silver particles to the multi-nano-sized silver particles is preferably 0.9 to 1, or 0.9 to 0.45, or 0.9 to 0.4, or 0.9 to 0.35, or 0.9 to 0.3, or 0.9 to 0.25, or 0.9 to 0.2, or 0.9 to 0.15, or 0.9 to 0.1, or 0.9 to 0.03 for Paste 2, such that the amount of multi-nano-sized silver particles is 1 to 10 wt. % of the paste composition.

Embodiments in accordance with the present disclosure further include another composition Paste 3 (nano) comprising:
(i) SF120 (D50 2 μm-D90 5 μm silver particles with a tapped density of 5 g/cc and a low calcium content of less than 10 ppm);
(ii) SF125 (D50 4.7 μm-D90 9 μm silver particles with a tapped density of 5.8 g/cc and a low calcium content of less than 10 ppm); and
(iii) S7000-95 BC nano silver (D50 50 nm with a tapped density of 3.1 g/cc and a low calcium content of less than 10 ppm dispersed in butyl carbitol (70.79 and 75% silver)).

The weight ratio of the multi-micron-sized silver particles to the multi-nano-sized silver particle is preferably 0.9 to 1, or 0.9 to 0.45, or 0.9 to 0.4, or 0.9 to 0.35, or 0.9 to 0.3, or 0.9 to 0.25, or 0.9 to 0.2, or 0.9 to 0.15, or 0.9 to 0.1, or 0.9 to 0.03 for Paste 3, such that the amount of multi-nano-sized silver particles is 1 to 10 wt. % of the paste composition.

Embodiments in accordance with the present disclosure further include another composition Paste 4 (non-nano) comprising a mixture of the two multi-micron-sized flake silver SF120 and SF125 as described for Paste 1. However, Paste 4 differs from Paste 1 in that Paste 4 has a high calcium content whereas Paste 1 has a low calcium content.

Embodiments in accordance with the present disclosure further include another composition Paste 5 (nano) comprising a mixture of the two multi-micron-sized flake silver SF120 and SF125 and nano silver S230 BC dispersed in butyl carbitol (70.29% silver) as described for Paste 2. However, Paste 5 differs from Pastes 2 and 3 in that Paste 5 has a high calcium content whereas Pastes 2 and 3 have a low calcium content.

### Exemplary Electrically Conductive Metal (Silver) Particles

Silver with a bulk resistivity of 1.59 μohm-cm, being the most conductive metal, is the most preferred metal component in the conductive metal paste formulation. The silver particles in the paste composition after sintering serve as die attach pad (DAP) and wire bond interconnect sites (PAD) to provide mechanical support, high electrical conductivity, and good thermal release property, as well as prevent downstream die attach adhesive leakage into the sintered silver features.

### Exemplary Micron-Sized Silver Particles

The micron-sized silver particles may include cubes, prisms, pyramids, cylinders, disks, ellipsoids, flakes, granules, needles, rings, rods, spheres, spheroids, or random non-geometric shapes. In particular, the particles may be flakes, spherical or spheroidal in shape. The micron-sized flake silver particles are the preferred silver particles for the Pastes 1 and 2.

The tapped density of the multi-micron-sized (or micron-sized) silver particles is preferably 3.6 g/cc or higher, the D90 is preferably between 1 μm and 20 μm, more preferably between 1 μm and 15 μm, most preferably between 5 μm and 15 μm. The silver particles are preferably coated with an organic acid during the silver powder fabrication (provided by vendor) to prevent particle agglomeration tendencies. The silver particles may include imbedded calcium residues due to the use of a surfactant containing calcium during the making process of the silver particles.

The calcium content of these silver particles should be as low as possible because calcium prevents the silver sintering process on coated stainless steel surface carriers due to an unknown mechanism which significantly reduces adhesion between the interfaces. The flake silver particles are commercially available from various suppliers such as Ames golden smith*, Metalor* and many other companies which should be apparent to those skilled in the art. The combination of the multi-micron-sized silver particles provides a special function for the sintered silver features to pass dye penetration test and prevents downstream die attach adhesive leakage into the bulk of the sintered silver features.

A combination of two or more multi-micron-sized silver particles is preferred in the paste composition. The weight ratio between the two silver particles (SF120 to SF125) is preferably 1 to 1, more preferably 1.5 to 1, more preferably 2 to 1, more preferably 2.5 to 1 more preferably 4 to 1, more preferably 4.5 to 1, more preferably 5 to 1, most preferably 3 to 1. In particular, the weight ratio of SF120 to SF125 for Paste 1 is 3:1 and the weight ratio of SF120 to SF125 for Paste 2 with nano silver is 4:1. The amount of flake silver particles in the silver pastes provided herein generally is greater than 50 wt. % of the paste composition. The amount of silver particles in the pastes provided herein may be from 51 to 95 wt. %, more preferably in the range from 60 to 90 wt. %, and most preferably in the range from 75 to 95 wt. % of the paste composition.

For example, the amount silver particles in the paste composition provided herein may be present in an amount that is 50.5 wt. %, 51 wt. %, 51.5 wt. %, 52 wt. %, 52.5 wt. %, 53 wt. %, 53.5 wt. %, 54 wt. %, 54.5 wt. %, 55 wt. %, 55.5 wt. %, 56 wt. %, 56.5 wt. %, 57 wt. %, 57.5 wt. %, 58 wt. %, 58.5 wt. %, 59 wt. %, 59.5 wt. %, 60 wt. %, 60.5 wt. %, 61 wt. %, 61.5 wt. %, 62 wt. %, 62.5 wt. %, 63 wt. %, 63.5 wt. %, 64 wt. %, 64.5 wt. %, 65 wt. %, 65.5 wt. %, 66 wt. %, 66.5 wt. %, 67 wt. %, 67.5 wt. %, 68 wt. %, 68.5 wt. %, 69 wt. %, 69.5 wt. %, 70 wt. %, 70.5 wt. %, 71 wt. %, 71.5 wt. %, 72 wt. %, 72.5 wt. %, 73 wt. %, 73.5 wt. %, 74 wt. %, 74.5 wt. %, 75 wt. %, 75.5 wt. %, 76 wt. %, 76.5 wt. %, 77 wt. %, 77.5 wt. %, 78 wt. %, 78.5 wt. %, 79 wt. %, 79.5 wt. %, 80 wt. %, 80.5 wt. %, 81 wt. %, 81.5 wt. %, 82 wt. %, 82.5 wt. %, 83 wt. %, 83.5 wt. %, 84 wt. %, 84.5 wt. %, 85 wt. %, 85.5 wt. %, 86 wt. %, 86.5 wt. %, 87 wt. %, 87.5 wt. %, 88 wt. %, 88.5 wt. %, 89 wt. %, 89.5 wt. %, 90 wt. %, 91.5 wt. %, 92 wt. %, 92.5 wt. %, 93 wt. %, 93.5 wt. %, 94 wt. %, 94.5 wt. % or 95 wt. % of the paste composition.

Exemplary Nano-Sized Silver Particles

Nanoscale or nano-sized silver particles (e.g., D50 between 10 nm and 150 nm) with a tapped density of 2.4 g/cc or higher is used in the paste composition under evaluation. The role of the nano-sized silver particles is to allow silver penetration into the gaps between DAP and PAD sintered silver features and metal oxide ink coated stainless steel substrate carrier for adhesion improvement. As aforementioned, this is one of the most critical specification of CSI™ semiconductor packaging process.

The nano-sized silver particles are coated with a fatty acid lubricant, polyvinylpyrrolidone (PVP) or any other compatible dispersants to prevent agglomeration during the powder making process by vendor. In other cases, the non-surface coated nano-sized silver particles may also be used with the dispersant agent to prevent agglomeration.

The nano-sized silver particles are commercially available from various suppliers such as Ames golden smith, Metalor, Nanostructured and Amorphous Materials Inc., Inframat Advanced Materials Inc., Sumitomo electronic USA Inc., and Kemoco Intentional Associations.

The amount of the nano-sized silver particles (e.g., in the form of dispersant coated or non-coated particles) in the paste composition of the present invention is preferably between 2.5 wt. % and 10 wt. %, more preferably between 2.5 wt. % and 9 wt. %, more preferably between 2.5 wt. % and 8 wt. %, more preferably between 2.5 wt. % and 7 wt. %, more preferably between 2.5 wt. % and 6 wt. %, most preferably between 2.5 wt. % and 5 wt. % of the silver paste composition.

The weight ratio of micron-sized silver particles to nano-sized silver particles in the Pastes 2 and 3 is preferably 0.9 to 0.45, preferably 0.9 to 0.4, preferably 0.9 to 0.35, preferably 0.9 to 0.3, preferably 0.9 to 0.25, preferably 0.9 to 0.2, preferably 0.9 to 0.15, preferably 0.9 to 0.1, more preferably 0.9 to 0.05, and most preferably 0.9 to 0.26. The calcium content of the nano-sized silver particles is preferably less than 20 ppm to prevent poor sintering of silver particles on the coated stainless steel substrate.

### Polymer Resin

A polymer resin is used as a carrier and viscosity adjustment agent for the screen and/or 3D printing process. It helps the dispersion of the materials during the manufacturing process. The resin may be selected with a molecular weight to be dissolved in a solvent in an amount of up to 10 wt. % of the paste composition. For example, the resins include synthetic or natural resins, such as bisphenol resin, cellulose resin, phenol resin, polyester, acrylic resin, coumarone resin, rosin resin, terpene resin, terpene phenol resin, styrene resin, xylene resin, polyvinyl alcohol, and alkyd resin.

Further examples of preferred resins include ethyl cellulose resins, rosin ester resins and acrylic resins. A most preferred ethyl cellulose resin in the paste composition has a molecular weight of 8,000 to 50,000 g/mol. Resins that may be included in paste composition provided herein should have one or more of the following characteristics:

(i) are compatible with the chosen organic solvent;
(ii) decompose quickly without leaving residues that negatively impact electric properties during the burnout phase at temperatures of approximately 250° C. to 500° C.; and
(iii) do not produce or release corrosive chemical entities or materials which will degrade the conductivity of the paste either after printing, thermal processing or during end-use.

Ideally, the resin selected herein should work in synergy with the inorganic ingredients of the paste composition to provide the appropriate paste rheology and sintered conductor properties.

The amount of resin in the paste composition provided herein generally is less than 10 wt. %, in particular in the range of 0.05 to 5 wt. % or in the range from 0.01 to 2 wt. % of the paste compositions. For example, the resin in the paste compositions provided herein may be present in an amount that is 0.01 wt. %, 0.025 wt. %, 0.05 wt. %, 0.075 wt. %, 0.1 wt. %, 0.125 wt. %, 0.15 wt. %, 0.175 wt. %, 0.2 wt. %, 0.225 wt. %, 0.25 wt. %, 0.275 wt. %, 0.3 wt. %, 0.325 wt. %, 0.35 wt. %, 0.375 wt. %, 0.4 wt. %, 0.425 wt. %, 0.45 wt. %, 0.475 wt. %, 0.5 wt. %, 0.75 wt. %, 1 wt. %, 1.25 wt. %, 1.5 wt. %, 1.75 wt. %, 2 wt. %, 2.25 wt. %, 2.5 wt. %, 2.75 wt. %, 3 wt. %, 3.25 wt. %, 3.5 wt. %, 3.75 wt. %, 4 wt. %, 4.25 wt. %, 4.5 wt. %, 4.75 wt. % or 10 wt. %.

### Solvent

The conductive silver pastes described herein include a solvent or a combination of solvents which evaporates after printing. Organic solvents with vapor pressure higher than 1 mmHg may be used in these paste compositions. Examples of solvents with a vapor pressure higher than 1 mmHg include butyl carbitol, 2,2,4-trimethyl-1,3pentanediol di-isobutyrate, 1-phenoxy-2-propanol, terpinol, texanol, toluene and mixtures of these solvents.

Organic solvents having a boiling point of 100° C. or greater and a low vapor pressure, such as 1 mmHg vapor pressure or less, may be also be used in similar applications. For example, a low vapor pressure solvent having a boiling point of between 100° C. to 250° C. may be selected.

Examples of low vapor pressure solvents include: dibasic ester mixture of dimethyl glutarate, dimethyl succinate (DBE 9 Dibasic Ester), 4-trimethyl-1,3-pentanediol monoisobutyrate (texanol); 3-butoxybutanol; N-methyl-pyrrolidone; tripropylene glycol-butyl ether (DOWANOL® TPnB); diethylene glycol monoethyl ether (Carbitol™); 2-butoxyethanol (Butyl Cellosolve®); dipropylene glycol monoethyl ether acetate (DOWANOL® DPMA); dipropylene glycol; benzyl alcohol; acetophenone; 1,2-dibutoxyethane (DibutylCellosolve®); phenoxy ethanol (Phenyl)Cellosolve®; trimethylpentanediolmonoisobutyrate propylene glycol phenylether (DOWNAL® PPh); dimethyl glutarate (DBES Dibasic Ester); hexylene glycol; dipropylene glycol n-butyl ether DOWANOL® DPnB; 2,4-heptanediol; phenyl carbitol; y-butyrolactone; diethylene glycol monobutyl ether; 2-(2-ethoxyethoxy) acetate; ethylene glycol; and terpineol. These low vapor pressure solvents may be used in the pastes provided herein, alone or in combination with high vapor pressure solvents.

The amount of solvent, whether present as a single solvent or a mixture of solvents, in the present pastes compositions is between 1 wt. % and 25 wt. % of the paste composition, particularly in the range from 3 to 16 wt. %, or in the range from 4 to 13 wt. %. For example, the conductive silver paste compositions provided herein may contain an amount of solvent that is 1 wt. %, 1.25 wt. %, 1.5 wt. %, 1.75 wt. %, 2 wt. %, 2.25 wt. %, 2.5 wt. %, 2.75 wt. %, 3 wt. %, 3.25 wt. %, 3.5 wt. %, 3.75 wt. %, 4 wt. %, 4.25 wt. %, 4.5 wt. %, 4.75 wt. %, 5%, 5.25 wt. %, 5.5%, 5.75 wt. %, 6 wt. %, 6.25 wt. %, 6.5 wt. %, 6.75 wt. %, 7 wt. %, 7.25 wt. %, 7.5 wt. %, 7.75 wt. %, 8 wt. %, 8.25 wt. %, 8.5 wt. %, 8.75 wt. %, 9 wt. %, 9.25 wt. %, 9.5 wt. %, 9.75 wt. %, 10 wt. %, 10.25 wt. %, 10.5 wt. %, 10.75 wt. %, 11 wt. %, 11.25 wt. %, 11.5 wt. %, 11.75 wt. %, 12 wt. %, 12.25 wt. %, 12.5 wt. %, 12.75 wt. %, 13 wt. %, 13.25 wt. %, 13.5 wt. %, 13.75 wt. %, 14 wt. %, 14.25 wt. %, 14.5 wt. %, 14.75 wt. %, 15 wt. %, 15.25 wt. %, 15.5 wt. %, 15.75 wt. %, 16 wt. %, 16.25 wt. %, 16.5 wt. %, 16.75 wt. %, 17 wt. %, 17.25 wt. %, 17.5 wt. %, 17.75 wt. %, 18 wt. %, 18.25 wt. %, 18.5 wt. %, 18.75 wt. %, 19 wt. %, 19.25 wt. %, 19.5 wt. %, 19.75 wt. %, or 25 wt. %.

### Dispersants

In metallic paste composition, small metal particles have a very high tendency to agglomerate and form large agglomerates due to their high surface energy. A dispersant is used as an anti-agglomeration agent through steric and/or electronic effects so that the dispersed polymer or organic acid coated metal particles are less prone to agglomeration. This could reduce or prevent sedimentation and provide a metal paste with good storage and printing stability. In the paste composition in which the metal particles are surface-treated with a dispersant or organic acid as an anti-agglomeration agent, the dispersant may be added to the paste composition containing the metal particles to enhance performance properties of the paste. Therefore, the dispersant can be added directly to the silver paste composition, or the silver particles can be surface-coated with the dispersant.

The total amount of dispersant in the silver paste composition is less than 7 wt. % of the paste composition. For example, the dispersant in the paste composition provided herein may be present in an amount that is 0.01 wt. %, 0.03 wt. %, 0.07 wt. %, 0.11 wt. %, 0.15 wt. %, 0.19 wt. %, 0.23 wt. %, 0.27 wt. %, 0.31 wt. %, 0.35 wt. %, 0.39 wt. %, 0.43 wt. %, 0.47 wt. %, 0.51 wt. %, 0.55 wt. %, 0.59 wt. %, 0.63 wt. %, 0 67 wt. %, 0.71 wt. %, 0.75 wt. % 0.79 wt. % 0.83 wt. % 0.87 wt. % 0.91 wt. %, 0.95 wt. %, 0.99 wt. %, 0.1.03 wt. %, 1.07 wt. %, 1.09 wt. %, 1.13 wt. %, 1.17 wt. %, 1.21 wt. %, 1.25 wt. %, 1.29 wt. %, 1.33 wt. %, 1.37 wt. %, 1.41 wt. %, 1.45 wt. %, 1.49 wt. %, 1.53%, 1.57 wt. %, 1.61 wt. %, 1.65 wt. %, 1.69 wt. %, 1.73%, 1.77 wt. %, 1.81 wt. %, 1.85 wt. %, 1.89 wt. %, 1.93 wt. %, 1.97 wt. %, 2.01 wt. %, 2.05 wt. %, 2.09 wt. %, 2.13 wt. %, 2.17 wt. %, 2.21 wt. %, 2.25 wt. %, 2.29 wt. %, 2.33 wt. %, 2.37 wt. %, 2.41 wt. %, 2.45 wt. %, 2.49 wt. %, 2.53 wt. %, 2.57 wt. %, 2.61 wt. %, 2.65 wt. %, 2.69 wt. %, 2.73 wt. %, 2.77 wt. %, 2.581 wt. %, 2.85 wt. %, 2.89 wt. %, 2.93 wt. %, 2.97 wt. % and 7 wt. %.

Examples of dispersants include but are not limited to: Solsperser™ hyper dispersant series (Lubrizol, Wickliffe, Ohio USA) which includes Solsperse™ 35000, Solsperse™ 32000, Solsperse™ 20000, and Solsperse™ 33000 which are solid polyethylene-imine cores grafted with polyester hyper dispersant; polycarboxylate ethers such as these in the Ethacryl series (Lyondell Chemical Company, Houston, Tex. USA) which includes Ethacryl 1030; Ethacryl HF series (water-soluble polycarboxylate copolymers) which includes Ethacryl M (polyether polycarboxylate sodium salt), Ethacryl 1000, Ethacryl G (water-soluble polycarboxylate copolymers containing polyalkylene oxide polymer); and copolymers with acidic groups, such as the BYK® series, which include phosphoric acid polyester (DISPERBYK® 111), BYK 9076, BYK 378, alkylolammonium salt of a polymer with acidic groups (DISPERBYK® 180), structured acrylic copolymer (DISPERBYK® 2008), structured acrylic copolymer with 2-butoxyethanol and 1-methoxy-2-propanol (DISPERBYK® 2009), block copolymer with pigment affinic groups (DISPERBYK® 2155).

### Additives

The conductive silver pastes provided herein may include other additives to enhance performance, such as an anti-agglomeration agent, a wetting agent, a viscosity modifier, a defoamer, a leveling agent, a sintering aid, and any combinations thereof. Examples of such additives that may be included in the conductive pastes provided herein include:
(i) Defoaming agents such as silicones, petroleum naphtha alkylate (BYK® 088), polysiloxane (BYK® 067 A), and blend of polysiloxanes, 2-butoxyethanol, 2-ethyl-1-hexanol and Stoddard solvent (BYK® 020); and silicone free defoaming agents, such as hydrodesulfurized petroleum naphtha, butyl glycolate and 2-butoxyethanol and combinations thereof (BYK® 052, BYK® A510, BYK® 1790, BYK® 354 and BYK® 1752);
(ii) Viscosity modifiers, such as SOLSPERSE™ 21000 polyester, acrylic polymers, 1-methyl-2-pyrrolidone (BYK® 410), allyl alcohol, hydroxyethyl cellulose, urea modified polyurethane (BYK® 425), and methyl cellulose;
(iii) Wetting agents that help in the wetting of the surface of a substrate or modify the surface tension. Examples of such as materials include polyether modified polydimethylsiloxane (BYK® 307), ethylbenzene, ethoxylates and a modified dimethylpolysiloxane copolymer wetting agent (Byk® 336), blend of xylene and ethylbenzene (BYK®3 10);
(iv) Leveling agents may be used to decrease surface tension and allow the paste to flow more readily during application and enhance the ability of the paste to wet a surface of the substrate. A fluorosurfactant, an organo-modified silicon, an acrylic leveling agent or a combination thereof; and
(v) Anti-agglomeration agents such as an organic polymer or a copolymer. Examples of anti-agglomeration agents include one or a combination of vinyl caprolactam, vinyl pyrrolidone, vinyl acetate, vinyl imidazole and polyvinyl pyrrolidone.

It is preferred that the additives be used in amounts less than 7% to minimize their effect on conductivity, however they could be used at higher amounts, such as between 1 to 15 wt. % based on the weight of the paste composition, in some instances.

As an example, the additives in the paste compositions provided herein may be present in an amount between 0.1 to 0.5 wt. %. The amount of additives, when present, may be 0.05 wt. %, 0.06 wt. %, 0.07 wt. %, 0.08 wt. %, 0.09 wt. %, 0.1 wt. %, 0.15 wt. %, 0.2 wt. %, 0.25 wt. %, 0.3 wt. %, 0.35 wt. %, 0.4 wt. %, 0.45 wt. %, 0.5 wt. %, 0.55 wt. %, 0.6 wt. %, 0.65 wt. %, 0.7 wt. %, 0.75 wt. %, 0.8 wt. %, 0.85 wt. %, 0.9 wt. %, 0.95 wt. %, 1.0 wt. %, 1.1 wt %, 1.2 wt. %, 1.3 wt. %, 1.4 wt. %, 1.5 wt. %, 1.6 wt. %, 1.7 wt. %, 1.8 wt. %, 1.9 wt. %, 2.0 wt. %, 2.1 wt. %, 2.2 wt. %, 2.3 wt. %, 2.4 wt. %, 2.5 wt. %, 2.6 wt. %, 2.7 wt. %, 2.8 wt. %, 2.9 wt. %, 3.0 wt. %, 3.1 wt. %, 3.2 wt. %, 3.3 wt. %, 3.4 wt. %, 3.5 wt. %, 3.6 wt. %, 3.7 wt. %, 3.8 wt. %, 3.9 wt. %, 4.0 wt. %, 4.1 wt. %, 4.2 wt. %, 4.3 wt. %, 4.4 wt. %, 4.5 wt. %, 4.6 wt. %, 4.7 wt. %, 4.8 wt. %, 4.9 wt. % or 7.0 wt. %.

The materials described hereinabove and the examples shown are compositional examples of pastes that could be used for applications where conductive pastes, such as silver paste composition, are utilized. An exemplary composition may include any combination of one or more of the components described hereinabove.

### Printing Process for Substrate Carrier

The stainless steel substrate carrier is first coated with metal oxide ink, sintered between 950° C. and 985° C. and patterned by photoresist to create the die attach pad (DAP) and wire bond interconnect sites (PAD) features onto which the silver pastes are to be printed and sintered. Exemplary PAD and DAP features are shown in FIG. 1.

The coating material uses a metal oxide ink and its sintering temperature is between 955° C. and 985° C. The coated stainless steel substrate may be laminated with a dry photoresist, UV cured with different masks and acid etched to obtain the die attached pad (DAP) and wire bond interconnect sites (PAD) features based on design rules and users' need for silver printing.

### Sintering

The conductive silver paste composition provided herein are typically screen and/or 3D printed on coated stainless substrate and then sintered, such as by heat treatment at temperatures between 500° C. and 900° C. The time and temperature used for sintering silver may however be adjusted accordingly. In this disclosure, the printed electronic silver features are sintered into conductive features at a temperature of approximately 600° C. to 900° C. from 1 minute to approximately 30 minutes or more. The silver sintering may be achieved using conduction ovens, IR ovens/furnaces, or by application of a photonic curing process, such as a highly focused laser or a pulsed light sintering system, or by induction.

### Analysis of PAD and DAP Features

The test measurements conducted on samples of Pastes 1, 2, 3, 4 and 5 after sintering are carried out and discussed hereinafter.

### Conductivity

The electrically conductive silver features by printing with the conductive silver pastes compositions provided herein exhibit excellent electrical properties. By way of a non-limiting example, the printed features should include a resistivity with good sintering that is not greater than about 5 times, or not greater than about 2 to 5 times the resistivity of the pure bulk metal, particularly when the sintering conditions allow the printed features to reach complete sintering. The sheet resistance of a printed silver paste feature is typically less than 5 ohm/sq, particularly less than 3 ohm/sq or less than 0.7 ohm/sq after sintering. The sintering may be achieved by using any method well-known in the art, such as in conduction ovens, IR ovens or furnaces, as well as through highly focused lasers or using pulsed light sintering systems, the conductivity may be measured utilizing a 4-point probe.

### Particle Size and Particle Size Distribution

A volume average particle size is measured by for example, using a Coulter Counter™ particle size analyzer. The median particle size may also be measured using conventional laser diffraction techniques. The mean particle size may also be measured using a Zetasizer Nano ZS device, utilizing the Dynamic Light Scattering (DLS) method.

### Printed Features Thickness and Dimension

An Optical Gaging Products (OGP) measuring scope is used to measure the thickness, x and y dimensions, or radius of the printed and sintered features.

### Adhesion of Printed Silver to Metal Oxide Ink Coated Stainless Steel Substrate

Die shear, die peel, microscope physical delamination inspection, tape test, automated delamination inspection methods are used to evaluate the adhesive strength.

### Die Attach Adhesive Leakage Trend of Printed Silver Feature

Dye penetration test is used to evaluate the die attach adhesive leakage of the printed silver features.

### Preparation of Paste Composition

The paste composition provided herein may be prepared using any method well known in the art, for example,

Step 1: The polymer resin Ethocellulose Std. 04 is mixed with butyl carbitol solvent to ensure complete dissolution of the resin;
Step 2: The silver particles comprising two or more mixtures of micron-sized silver particles and nano-sized silver particles and any other components of the paste, for example, dispersant and additives such as wetting agent and others, are added and mixed until a homogeneous paste is obtained; and
Step 3: The resultant homogenous paste is milled using any type of grinding mill, such as a bead mill, media mill, ball mill, two-roll mill, three-roll mill, and air-jet mill. For example, the paste may be repeatedly passed through a 3-roll mill (e.g., Exakt Technology). During milling using the 3-roll mill, the gaps may be progressively reduced, such as from 30 μm to 10 μm, in order to achieve a grind reading (i.e., dispersion) of the desired silver particle size of less than or equals to 10 μm.

The samples of silver Pastes 1, 2, 3, 4 and 5 as prepared are shown in Tables 1 to 5.

TABLE 1
Paste 1 comprising: A mixture of two multi-micron-sized flake silver particles
(i) SF120 (D50 2 μm, D90 5 μm tapped density 5 g/cc, low calcium
content); and (ii) SF125 (D50 4.7 μm, D90 9 μm, tapped density 5.8
g/cc, low calcium content). This Paste is used as control for adhesion study.

| | | | | | | | |
|---|---|---|---|---|---|---|---|
| | | | | Target | Weight | Order of | Special |
| Component | Vendor | Lot # | Calcium | Mass (g) | (%) | Addition | Instructions |

Powders

| | | | | | | |
|---|---|---|---|---|---|---|
| SF120 | Ames | Lot 1 | <10 ppm | 36.640 | 22.86 | 3 |
| SF125 | Ames | Lot 1 | <10 ppm | 109.904 | 68.56 | 4 |

Resin and Solvent

| | | | | | | |
|---|---|---|---|---|---|---|
| Ethocellulose | Sigma | Lot 1 | 2.420 | 1.51 | 1 | |
| Std 04 | Aldrich | | | | | |
| Butyl Carbitol | Sigma | Lot 1 | 11.130 | 6.95 | 2 | Add additional |
| | Aldrich | | | | | 0.2 wt. % after |
| | | | | | | 3 roll mill |

TABLE 2
Paste 2 comprising: A mixture of two multi-micron-sized flake silver particles
(i) SF120 and SF125; and (ii) S230 BC nano silver (D50 50 nm, tapped density
2.4 g/cc, low calcium content), dispersed in butyl carbitol (70.29% silver).

| | | | | | | | |
|---|---|---|---|---|---|---|---|
| | | | | Target | Weight | Order of | Special |
| Component | Vendor | Lot # | Calcium | Mass (g) | (%) | Addition | Instructions |

Powders

| | | | | | | |
|---|---|---|---|---|---|---|
| SF125-69 | Ames | Lot 1 | <10 ppm | 113.920 | 71.20 | 3 |
| SF120-69 | Ames | Lot 1 | <10 ppm | 28.480 | 17.80 | 4 |
| S230BC | Ames | Lot 1, | <10 ppm | 5.7 | 2.6 | 5 |
| | | Lot 2 | | (70.29% | (silver | |
| | | | | silver) | only) | |

Resin and Solvents

| | | | | | | |
|---|---|---|---|---|---|---|
| Ethocellulose | Sigma | | 2.440 | 1.53 | 1 | |
| Std 04 | Aldrich | | | | | |
| Butyl Carbitol | Sigma | Lot 1 | 11.150 | 6.97 | 2 | Add additional |
| | Aldrich | | | | | 0.2 wt. % of |
| | | | | | | paste after 3 |
| | | | | | | roll mill |

TABLE 3
Paste 3 comprising: A mixture of two multi-micron-sized flake silver particles (i)
SF120 and SF125; and (ii) S7000-95 BC nano silver (D50 50 nm, tapped density 3.1
g/cc, low calcium content) dispersed in butyl carbitol (70.79 and 75% silver).

| | | | | | | | |
|---|---|---|---|---|---|---|---|
| | | | | Target | Weight | Order of | Special |
| Component | Vendor | Lot # | Calcium | Mass (g) | (%) | Addition | Instructions |

Powders

| | | | | | | | |
|---|---|---|---|---|---|---|---|
| SF125-69 | Ames | Lot 1 | <10 ppm | 113.920 | 71.20 | 3 | — |
| SF120-69 | Ames | Lot 1 | <10 ppm | 28.480 | 17.80 | 4 | — |
| S7000-95 BC | Ames | Lot 1, | <10 ppm | 5.7 | 2.6 | 5 | — |
| | | Lot 2 | | (70.79% | (silver) | | |
| | | | | and 75% | | | |
| | | | | silver) | | | |

Resin and Solvents

| | | | | | | | |
|---|---|---|---|---|---|---|---|
| Ethocellulose | Sigma | Lot 1 | — | 2.440 | 1.53 | 1 | — |
| Std 04 | Aldrich | | | | | | |
| Butyl Carbitol | Sigma | Lot 1 | — | 11.150 | 6.97 | 2 | Add additional |
| | Aldrich | | | | | | 0.2 wt. % of |
| | | | | | | | paste after 3 |
| | | | | | | | roll mill |

TABLE 4
Paste 4 comprising: A mixture of two multi-micron-sized flake
silver particles SF120 and SF125 (high calcium content)

| | | | | | | | |
|---|---|---|---|---|---|---|---|
| | | | | Target | Weight | Order of | Special |
| Component | Vendor | Lot # | Calcium | Mass (g) | (%) | Addition | Instructions |

Powders

| | | | | | | | |
|---|---|---|---|---|---|---|---|
| SF120-69 | Ames | Lot 1 | <10 ppm | 36.640 | 22.86 | 3 | — |
| SF125-69 | Ames | Lot 2, | 71 ppm, | 109.904 | 68.56 | 2 | — |
| | | Lot 3, | 76 ppm, | | | | |
| | | Lot 4 | 82 ppm | | | | |

Resin and Solvent

| | | | | | | | |
|---|---|---|---|---|---|---|---|
| Ethocellulose | Sigma | — | — | 2.420 | 1.51 | 1 | — |
| Std 04 | Aldrich | | | | | | |
| Butyl Carbitol | Sigma | Lot 1 | — | 11.130 | 6.95 | 4 | Add additional |
| | Aldrich | | | | | | 0.2 wt. % after |
| | | | | | | | 3 roll mill |

TABLE 5
Paste 5 comprising: A mixture of two multi-micron-sized flake silver
particles (i) SF120 and SF125; and (ii) Nano silver S230 BC dispersed
in butyl carbitol (70.29% silver) (high calcium content).

| | | | | | | | |
|---|---|---|---|---|---|---|---|
| | | | | Target | Weight | Order of | Special |
| Component | Vendor | Lot # | Calcium | Mass (g) | (%) | Addition | Instructions |

Powders

| | | | | | | | |
|---|---|---|---|---|---|---|---|
| SF125-69 | Ames | Lot 1 | <10 ppm | 113.920 | 71.20 | 3 | — |
| SF120-69 | Ames | Lot 1 | <10 ppm | 28.480 | 17.80 | 4 | — |
| S230BC | Ames | Lot 2, | 110 ppm, | 5.7 | 2.6 | 5 | — |
| | | Lot 3 | 850 ppm | (70.29% silver) | (silver) | | |

Resin and Solvents

| | | | | | | | |
|---|---|---|---|---|---|---|---|
| Ethocellulose | Sigma | — | — | 2.440 | 1.53 | 1 | — |
| Std. 04 | Aldrich | | | | | | |
| Butyl Carbitol | Sigma | MKBS | — | 11.150 | 6.97 | 2 | Add additional |
| | Aldrich | 8503v | | | | | 0.2 wt. % of |
| | | | | | | | paste after 3 |
| | | | | | | | roll mill |

The nano-sized silver particles are obtained from Ames Advanced Materials. The flake powder SF120 (D90 5 μm, tapped density 5 g/cc) and flake silver powder SF125 (D90 9 μm, tapped density 5.8 g/cc) are also obtained from Ames Advanced Materials. The solvent butyl carbitol and polymer resin Ethocellulose Std. 04 are obtained from Sigma Aldrich.

TABLE 6
A summary of the respective Pastes' composition.

| Paste 1 | Paste 2 | Paste 3 | Paste 4 | Paste 5 |
|---|---|---|---|---|
| A mixture of | A mixture of | A mixture of | A mixture of | A mixture of |
| two multi- | two multi- | two multi- | two multi- | two multi- |
| micron-sized | micron-sized | micron-sized | micron-sized | micron-sized |
| particle flake | particle flake | particle flake | particle flake | particle flake |
| silver SF120 | silver SF120 | silver SF120 | silver SF120 | silver SF120 |
| and SF125 only. | and SF125; | and SF125; | and SF125 only. | and SF125; |
| (This Paste is | and S230 BC | and S7000-95 | | and S230 BC |
| used as control | nano silver. | BC nano silver. | | nano silver. |
| for adhesion | | | | |
| study.) | | | | |
| SF120 | SF120 | SF120 | SF120 | SF120 |
| D50 2 μm, | D50 2 μm, | D50 2 μm, | D50 2 μm, | D50 2 μm, |
| D90 5 μm, | D90 5 μm, | D90 5 μm, | D90 5 μm, | D90 5 μm, |
| tapped density 5 | tapped density 5 | tapped density 5 | tapped density 5 | tapped density 5 |
| g/cc, | g/cc, | g/cc, | g/cc, | g/cc, |
| low calcium | low calcium | low calcium | low calcium | low calcium |
| content | content | content | content | content |
| (<10 ppm) | (<10 ppm) | (<10 ppm) | (<10 ppm) | (<10 ppm) |
| SF125 | SF125 | SF125 | SF125 | SF125 |
| D50 4.7 μm, | D50 4.7 μm, | D50 4.7 μm, | D50 4.7 μm, | D50 4.7 μm, |
| D90 9 μm, | D90 9 μm, | D90 9 μm, | D90 9 μm, | D90 9 μm, |
| tapped density | tapped density | tapped density | tapped density | tapped density |
| 5.8 g/cc, | 5.8 g/cc, | 5.8 g/cc, | 5.8 g/cc, | 5.8 g/cc, |
| low calcium | low calcium | low calcium | high calcium | low calcium |
| content | content | content | content | content |
| (<10 ppm) | (<10 ppm) | (<10 ppm) | (71 ppm, 76 | (<10 ppm) |
| | | | ppm, 82 ppm) | |
| — | S230 BC nano | S7000-95 BC nano | — | S230 BC nano |
| | silver dispersed | silver dispersed | | silver dispersed |
| | in butyl carbitol | in butyl carbitol | | in butyl carbitol |
| | (70.29% silver) | (70.79% and 75% | | (70.29% silver) |
| | D50 50 nm, | silver) | | D50 50 nm, |
| | tapped density | D50 50 nm, | | tapped density |
| | 2.4 g/cc, | tapped density | | 2.4 g/cc, |
| | low calcium | 3.1 g/cc, | | high calcium |
| | content | low calcium | | content |
| | (<10 ppm) | content | | (110 ppm and |
| | | (<10 ppm) | | 850 ppm) |
| Temperatures | Temperatures | Temperatures | Temperatures | Temperatures |
| for stainless | for stainless | for stainless | for stainless | for stainless |
| steel coating | steel coating | steel coating | steel coating | steel coating |
| metal oxide ink | metal oxide ink | metal oxide ink | metal oxide ink | metal oxide ink |
| sintering: 955° C. | sintering: 955° C. | sintering: 955° C. | sintering: 955° C. | sintering: 955° C. |
| to 985° C.; | to 985° C.; | to 985° C.; | to 985° C.; | to 985° C.; |
| Temperature for | Temperature for | Temperature for | Temperature for | Temperature for |
| printed silver | printed silver | printed silver | printed silver | printed silver |
| sintering: | sintering: | sintering: | sintering: | sintering: |
| 860° C. | 860° C. | 860° C. | 860° C. | 860° C. |

Three types of masks (e.g., Masks A, B and C) are used to perform photoresist patterning process for all five pastes to create different printing features:

(i) Mask A combined with 6 layers silver paste screen printing;
(ii) Mask B combined with 5 layers silver paste screen printing; and
(iii) Mask C combined with 6 layers silver paste screen printing.

The different Masks A, B and C each represents different silver features and sizes for different customers. The same screen printer, stainless steel substrate coating metal oxide ink, sintering condition and printing conditions are used for the printed and sintered silver features evaluations. In the test using nano silver Pastes 2 or 3, the nano silver paste is only printed at the bottom layer in contact with the stainless steel substrate, for the rest of 4 or 5 layers above the bottom layer, the micron-sized silver Paste 1 is used for printing. In the tests, the temperatures for stainless steel coating metal oxide ink sintering is from 955° C. to 985° C. and temperature for printed silver sintering is 860° C.

Adhesion improvement between sintered silver features and coated stainless steel substrate carrier interfaces will make the semiconductor packaging process more robust and increase final yield for downstream calendaring press, die attach, wire bond, polymer molding, stainless substrate peeling, soldering processes, as well as usage reliability tests. The adhesion strength between sintered silver features and metal oxide ink coated stainless steel substrate carrier is used as the key index factor in the following test results to show the benefit of utilizing multi-micron-sized and nano-sized silver flakes combination pastes for the CSI™ semiconductor packaging method.

### Test Results

The peel adhesion of sintered silver die attach pad (DAP), and the shear adhesion of sintered silver wire bond interconnect sites (PAD), as shown in FIG. 3b, is measured for different tests using Paste 1 to Paste 5, before and after the calendaring process.

The high power microscope inspection for delamination between the sintered silver features and coated stainless steel substrate is conducted to provide comparison between Paste 1 to Paste 5. The results are explained in the following paragraphs.

TABLE 7
A summary of the different processes and conditions of the metal oxide ink sintering
temperature, printer used, printing layers, mask type tests and respective results.

| Test | Test Objectives | Part A | Part B | Part C | Part D |
|---|---|---|---|---|---|
| Section | (i) Compare | (i) Compare | (i) Compare | (i) Compare | (i) Compare |
| I | non-nano silver | Paste 1 and Lot | Paste 1 and Lot | Paste 1 and Lot | Paste 1 and Lot |
| | Paste 1 and nano | 1 of Paste 2 with | 1 of Paste 2 with | 1 of Paste 2 with | 2 of Paste 2 with |
| | silver Paste 2; | low calcium | low calcium | low calcium | low calcium |
| | (ii) Perform | silver using | silver at various | silver using | silver using |
| | nano silver | manual R&D | metal oxide | automated high | manual R&D |
| | adhesion | tool; | sintering | volume tool. | tool. |
| | mechanism | (ii) Evaluate | temperatures | | |
| | study. | nano silver | using R&D tool. | | |
| | | adhesion | | | |
| | | improvement | | | |
| | | mechanism. | | | |
| Section | (i) Compare | (i) Compare | (i) Compare | — | — |
| II | non-nano silver | Paste 1 and Lot | Paste 1 and Lot | | |
| | Paste 1 and nano | 1 of Paste 3 with | 2 of Paste 3 with | | |
| | silver Paste 3. | low calcium | low calcium | | |
| | | silver using | silver using | | |
| | | manual R&D | manual R&D | | |
| | | tool. | tool. | | |
| Section | (i) Evaluate | (i) Compare | (i) Compare | — | — |
| III | calcium effect | Paste 1 and | Pastes 1, 2 and 5 | | |
| | on silver | various lots of | with low and | | |
| | sintering. | Paste 4 with low | high calcium | | |
| | | and high | silver using | | |
| | | calcium silver | manual R&D | | |
| | | using manual | tool. | | |
| | | R&D tool; | | | |
| | | (ii) Evaluate | | | |
| | | calcium effect | | | |
| | | on silver | | | |
| | | sintering | | | |
| | | mechanism. | | | |

### Section I: Pastes 1 and 2, Part A, Part B, Part C, Part D Nano Silver and Non-Nano Silver Samples Adhesion Comparisons and Adhesion Improvement Root Cause Test Results

The test results from Section I experimental set-up show that the sintered silver feature conductivity for Pastes 1 and 2 are similar to each other (e.g., approximately 1.6 μohm-cm). In addition, the dimension and height of the sintered silver features for Pastes 1 and 2 are also similar. In the experimental set-up, 8 mil coated stainless steel substrate, Mask A or B, Ekra printer, BTU furnace for silver sintering at 860° C. and stainless steel coating material sintering at 955° C.-985° C. were used. The control uses non-nano silver Paste 1: Print 6 layers for Mask A parts and 5 layers for Mask B parts. The print parameters are as shown below in Table 8. In addition, other output variables includes PAD and DAP off (delamination from stainless steel substrate) microscope inspection after silver sintering, calendaring and polymer molding, PAD shear, DAP peel, tape test and dye penetration test.

TABLE 8
A summary of print parameters for Section I experimental set-up.

| | Speed (mm/min) | Pressure (Psi) | Position |
|---|---|---|---|
| First layer - First print | 10 | 3 | 0 |
| First layer - Second print | 10 | 1 | 0 |
| Second to fifth layers | 30 | 3 | 0 |
| Sixth layer | 30 | 4 | 0 |

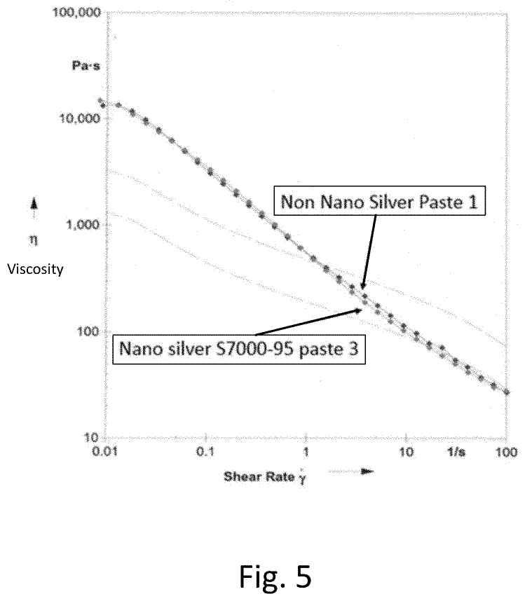

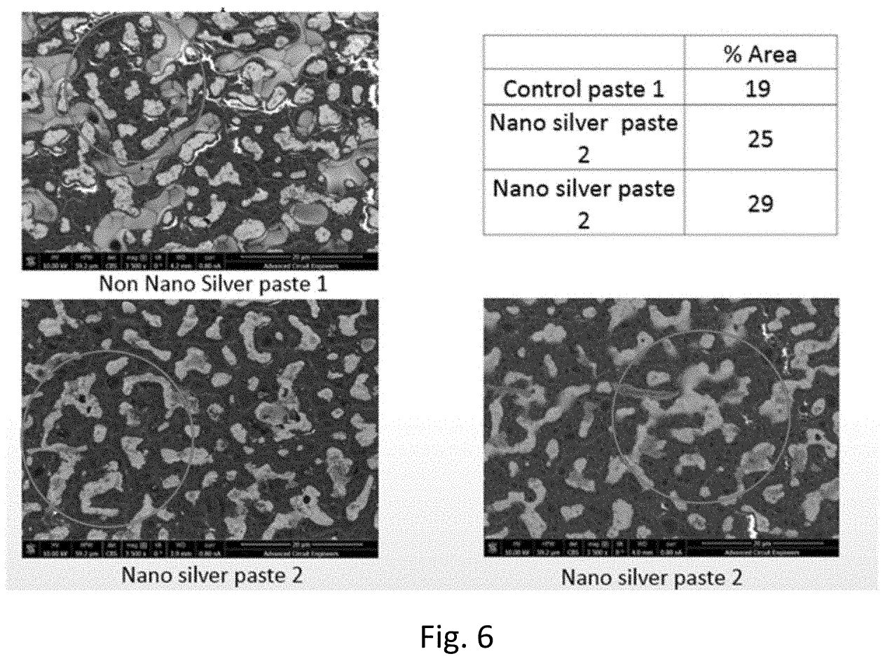

The rheology curves of Pastes 1, 2 and 3 measured by a cone-plate rheometer (Physica MCR101), as shown in FIGS. 5 and 6, are similar. In the viscosity range of 10 to 400 Pa·s at a shear rate of 10 sec⁻¹ at 25° C., Pastes 1, 2 and 3 are shown to be suitable for screen printing.

Pastes 1 and 2 sintered silver features passed the tests with respect to dye penetration, tape test, and microscope delamination inspection. These tests are utilized for the purpose of testing die attach epoxy leakage into the bulk of the sintered silver and silver adhesion to metal oxide ink coated stainless steel substrate. In customers' tests, Pastes 1 and 2 printed and sintered parts also passed the downstream die attached, wire bond, polymer molding, substrate peeling, soldering processes, and device reliability tests using this CSI™ packaging method. In other words, Pastes 1 and 2 may both can be used for the applications of CSI™ semiconductor packaging process.

The further comparisons between Pastes 1 and 2 for adhesive strength between coated stainless steel substrate carrier and sintered silver features are shown in the following Parts A to D tests.

### Section I—Part A Test

In the Part A test, Mask B, stainless steel coating material sintering at 960° C. and silver sintering at 860° C. are used. The sample size for the adhesive strength test is to measure 50 DAPs for peel strength and/or 50 PADs for shear strength for each silver type per stainless steel carrier strip. Table 9 shows the control non-nano silver paste 1 and nano silver paste 2 silver DAP and silver PAD adhesion comparison.

The results indicate that the nano silver PAD shear adhesion (kgf) to coated stainless steel substrate improved by approximately 42%, the nano silver DAP peel adhesion (gf) to coated stainless steel substrate improved by approximately 30% and nano silver samples have much lower percentage PAD delamination after calendaring and mold peel processes when compared to non-nano silver samples.

TABLE 9
Control non-nano silver Paste 1 and nano silver Paste 2 silver DAP
and silver PAD adhesion comparison in Part A test: Sintered silver
PAD shear and silver DAP peel tests results (B mask, stainless steel
coating sintering at 960° C. and silver sintering at 860° C.)

| | Pad Shear (kgf, 50 | | DAP Peel (gf, 50 | | PAD off before | Extra PAD off |
|---|---|---|---|---|---|---|
| Panel ID | sample each panel) | | samples each panel) | | mold peel | after mold peel |
| Nano | Average | Std dev | Average | Std dev | — | — |
| Silver | | | | | | |
| Paste 2 | | | | | | |
| A | 0.33 | 0.02 | 200.1 | 11.7 | Very few | 1 |
| B | 0.29 | 0.02 | 186 | 9 | Very few | 0 |
| C | 0.28 | 0.04 | 184 | 18 | Very few | 0 |
| D | 0.31 | 0.03 | 193 | 14.4 | Very few | 0 |
| Avg | 0.3 | 0.03 | 190.7 | 13.275 | — | — |
| Non-Nano | 0.21 | 0.02 | 147 | 20.2 | Significant | 4 |
| Silver | | | | | | |
| Paste 1 | | | | | | |
| (Control) | | | | | | |
| | 42% | — | 30% | — | — | — |
| | increase | | increase | | | |

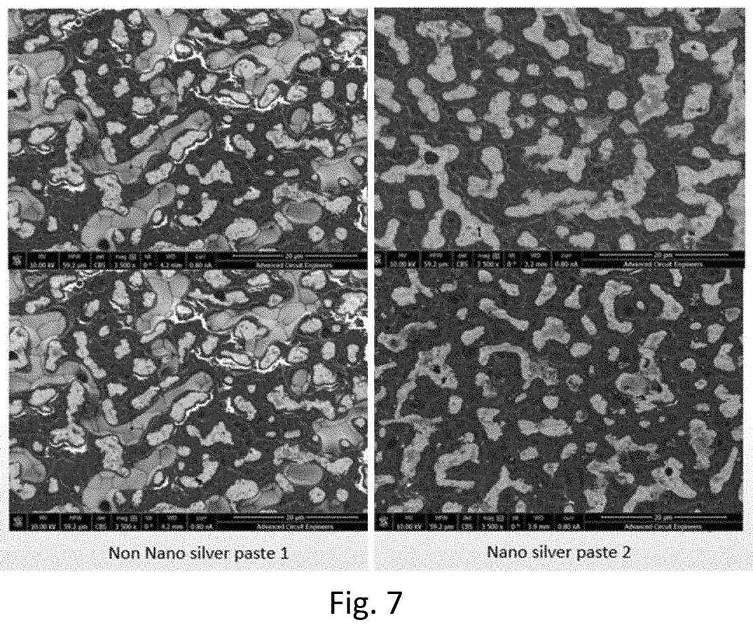

Scanning electron microscope (SEM) is used to examine the silver die attach pad (DAP) contact surface area and morphology between the special material coated stainless steel layer and sintered silver layer. This is done by peeling the special material coated stainless steel substrate off polymer molded samples after polymer molding procedure. The SEM pictures for Pastes 1 and 2 are shown in FIGS. 6 and 7 for the silver DAP contact surface area and morphology between special material coated stainless steel and sintered silver layers.

As aforementioned, the interface between the metal oxide coated stainless steel substrate and sintered silver layers is expected to have tiny gaps. The role of the nano-sized silver particles is to enhance silver particles penetration into the gaps between the sintered silver layer and the metal oxide material coated stainless steel substrate layers, thus increasing the interface contact area and resulting in improved adhesion. The SEM images shown in FIGS. 6 and 7 confirm the mechanism that the nano-sized silver particles are able to change contact morphology from smaller contact to longer contact shape, and increase total contact surface area to improve adhesion of the sintered silver layers to the metal oxide ink coated stainless steel substrate.

### Section I—Part B Test

In Part B test, Masks A and B, stainless steel coating material sintering at 955° C.-985° C. and 860° C. silver sintering at 860° C. are used. The sample size for each test is 50 PAD and 50 DAP for each type of silver per stainless steel strip (5 strips for each condition is used in this test).

The results as shown in Tables 10A and 10B indicate that the nano silver containing Paste 2 silver PAD shear adhesion to coated stainless steel substrate improved by approximately 40% and the nano silver containing Paste 2 silver DAP peel adhesion to coated stainless steel substrate improved by approximately 30% when compared to non-nano silver Paste 1 control at various metal oxide ink sintering temperatures. The results also indicate that the lower the sintering temperature of metal oxide ink, the better the DAP peel adhesion between the sintered silver and metal oxide coated stainless steel substrate.

TABLE 10A
Control non-nano silver Paste 1 and nano silver Paste 2 silver
DAP and silver PAD adhesion comparison with different stainless
steel coating materials sintering temperatures in Part B test:
Sintered silver PAD shear and silver DAP peel tests results
(Masks A and B, stainless steel coating sintering at 955°
C.-985° C. and silver sintering at 960° C.).

| | | | DAP Peel | | |
|---|---|---|---|---|---|
| | | Pretreat | (gf, 50 samples) | | |
| Sample | Mask | Temp | Average | Std dev | % Increase |
| Control | B | 985 | 101 | — | — |
| Nano silver | B | 985 | 110 | 7 | 9 |
| Control | B | 970 | 132 | 13 | — |
| Nano silver | B | 970 | 162 | 9 | 23 |
| Control | B | 960 | 147 | 14 | — |
| Nano silver | B | 960 | 190 | 20 | 30 |
| Control | B | 955 | 198 | 6 | — |
| Nano silver | B | 955 | 260 | 26 | 32 |

TABLE 10B
Control non-nano silver Paste 1 and nano silver Paste 2 silver
DAP and silver PAD adhesion comparison with different stainless
steel coating materials sintering temperatures in Part B test:
Sintered silver PAD shear and silver DAP peel tests results
(Masks A and B, stainless steel coating sintering at 955°
C.-985° C. and silver sintering at 960° C.).

| | | | PAD Shear | | |
|---|---|---|---|---|---|
| | | Pretreat | (kgf, 50 samples) | | |
| Sample | Pattern | Temp | Average | Std dev | % Increase |
| Control | B | 985 | 0.297 | 0.04 | — |
| Nano silver | B | 985 | 0.339 | 0.035 | 14.4 |
| Control | A | 985 | 0.503 | 0.035 | — |
| Nano silver | A | 985 | 0.577 | 0.058 | 14.3 |
| Control | B | 970 | 0.368 | 0.034 | — |
| Nano silver | B | 970 | 0.41 | 0.023 | 11.4 |
| Control | B | 960 | 0.3 | 0.03 | — |
| Nano silver | B | 960 | 0.21 | 0.02 | 40 |
| Control | B | 955 | 0.4 | 0.027 | — |
| Nano silver | B | 955 | 0.406 | 0.015 | 1.5 |
| Control | A | 955 | 0.649 | 0.038 | — |
| Nano silver | A | 955 | 0.655 | 0.049 | 0.9 |

### Section I—Part C Test

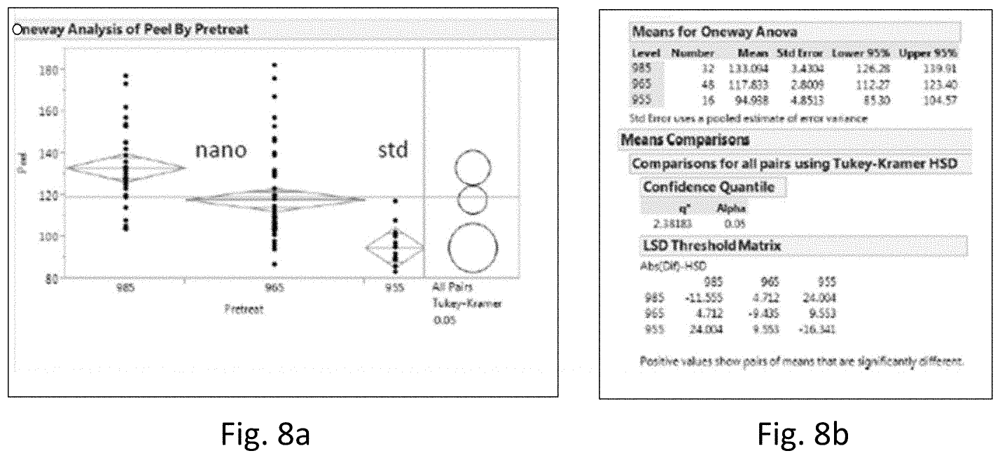

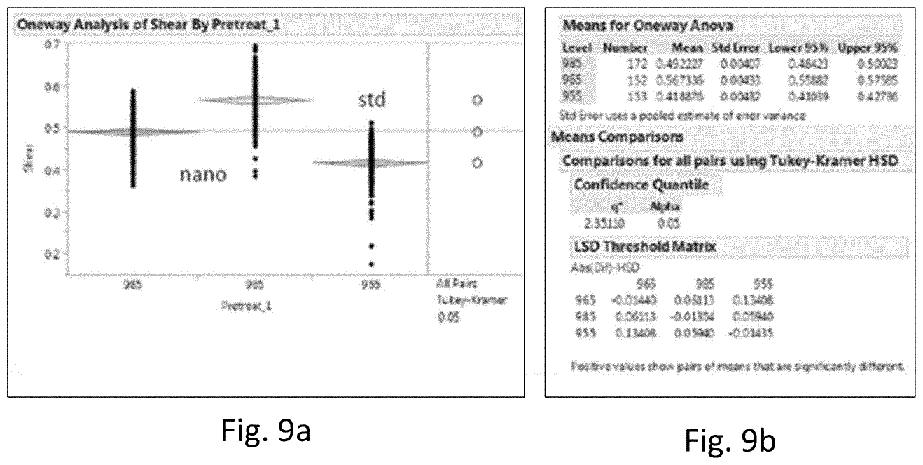

In Part C test, Mask C, stainless steel coating material sintering at 955° C.-985° C. and silver sintering at 860° C. are used. The total samples size for the tests includes several hundred silver DAP and PAD features. The results shown in Tables 11 and 12 indicate that the nano silver Paste 2, PAD shear adhesion to substrate improved by approximately 20-37%, the nano silver Paste 2, DAP peel adhesion to substrate improved by approximately 20-40% when compared to non-nano silver Paste 1 samples and the nano silver Paste 2 samples has 600% less silver PAD delamination rate after calendaring and mold peel when compared to non-nano silver samples. The difference of adhesion between nano silver and non-nano silver samples for the adhesion is statistically significant as shown in FIGS. 8a-8b and 9a-9b, as well as Table 11.

In FIG. 8a, the peel adhesion comparison done by automated high volume manufacturing process in Penang, Malaysia, shows that the difference between the groups of control non-nano silver Paste 1 and nano silver Paste 2 silver DAP and silver PAD is statistically significant based on the calculations as shown in FIG. 8b.

In FIG. 9a, the sheer adhesion comparison by Penang, Malaysia, in automated high volume manufacturing process, shows that the difference between the groups of control non-nano silver Paste 1 and nano silver Paste 2 silver DAP and silver PAD is statistically significant based on the calculations as shown in FIG. 9b.

TABLE 11
Control non-nano silver Paste 1 and nano silver Paste 2 silver DAP and silver
PAD pad off rate comparison by Penang, Malaysia, in high volume manufacturing
process. As shown, the nano silver pad off reduction rate is up to 600%.

| | | | Pad off number | |
|---|---|---|---|---|
| | Total Pad | Strip showed | for strip showed | Pad off rate |
| | off number | pad off | pad off | reduction |
| C mask past 1, 955° C. pre- | 18 | 7 out of 45 | 2, 1, 1, 1, 7, 5, 1 | |
| treat, non-nano silver | | | | |
| AC mask G1 Con 204- | 3 | 1 out of 45 | 3 | 600% |
| 965° C. pre-treat, nano silver | | | | |
| Amkor G1 Con 204-985° C. | 2 | 2 out of 45 | 1, 1 | 600% |
| pre-treat, nano silver | | | | |

### Section I—Part D Test

In Part D test, Mask B, stainless steel coating material sintering at 970° C. and silver sintering at 860° C., and another batch of S230BC nano silver with 110 ppm calcium are used. The sample size for the test is 50 PAD or 50 DAP for each type of silver per substrate strip (3 strips are used in this case).

The results as shown in Table 12 indicate that the nano silver Paste 2, silver DAP peel adhesion increase by approximately 9% and 14% respectively before and after calendaring. The nano silver Paste 2, silver PAD shear adhesion increased by approximately 1% and 8% respectively before and after calendar. Both the control non-nano silver and nano silver samples' silver PAD shear adhesion after calendaring increased at approximately 94% and 107% respectively. Both control non-nano silver and nano silver samples silver DAP peel adhesion after calendar increased by approximately 2% and 5% respectively.

TABLE 12
Control non-nano silver Paste 1 and nano silver Paste 2 (Lot 2) silver
DAP and Silver PAD adhesion comparison in Part D test (Mask B, stainless
steel coating sintering at 970° C. and silver sintering at 860° C.).

| | | Sample | | | | | |
|---|---|---|---|---|---|---|---|
| | | Con184- | | Nano | Nano | Nano | |
| | | control | | silver | silver | silver | |
| | | (19495) | Avg | (19496) | (19597) | (19498) | Avg |
| PAD shear | Average | 0.124 | 0.124 | 0.12 | 0.135 | 0.121 | 0.1253 |
| before calendar | from 48 PAD | | | | | | |
| | Stdev | 0.009 | 0.009 | 0.007 | 0.005 | 0.006 | 0.006 |
| PAD shear | Average | 0.24 | 0.24 | 0.264 | 0.275 | 0.239 | 0.2593 |
| after calendar | from 48 PAD | | | | | | |
| | Stdev | 0.016 | 0.016 | 0.017 | 0.013 | 0.017 | 0.0157 |
| % shear increasing by calendar | | — | 94% | — | — | — | — |
| Nano silver % shear increased | | — | 107% | — | — | — | 1.1%, 8% |
| before and after calendar | | | | | | | |
| DAP peel | Average | 112.5 | 112.5 | 119.5 | 127.13 | 119.88 | 122.17 |
| before calendar | from 8 DAP | | | | | | |
| | Stdev | 7.98 | 7.98 | 6.41 | 7.88 | 3.18 | 5.8233 |
| DAP peel after | Average | 114.1 | 114.1 | 129.8 | 128.93 | 126.8 | 128.51 |
| calendar | from 8 DAP | | | | | | |
| | Stdev | 12.3 | 12.3 | 5.1 | 11.7 | 3.7 | 6.8333 |

| | | | | | | |
|---|---|---|---|---|---|---|
| % peel increased by calendar | — | 2% | — | — | — | 5% |
| Nano silver % peel increased | — | — | — | — | — | 9%, 14% |
| before and after calendar | | | | | | |

Section II: Pastes 1 and 3 (S7000-95 Nano Silver with Low Calcium Content) in Part a and Part B, Non-Nano Silver and Nano Silver Samples Adhesion Test Results

The test results from Section II, Pastes 1 and 3 experimental set-up shows that the sintered silver resistivity for Pastes 1 and 3 are similar to each other (e.g., approximately 1.59 μohm-cm). In addition, the dimensions and heights of the sintered silver features for Pastes 1 and 3 are also similar. In the experimental set-up, 8 mil coated stainless steel substrate, Mask A or B, Ekra printer, BTU furnace for silver sintering at 860° C. and stainless steel coating material sintering at 955° C.-985° C. were used. The control uses non-nano silver Paste 1: Print 6 layers for Mask A parts and 5 layers for Mask B parts, and nano silver Paste 3 Print bottom first layer with nano silver Pastes 3 and 5, or 4 other layers with Paste 1 using Mask A or B. The print parameters are as shown below in Table 13. In addition, other output variables includes PAD and DAP off (delamination from stainless steel substrate) microscope inspection after silver sintering, calendaring and polymer molding, PAD shear, DAP peel, tape test and dye penetration test.

TABLE 13
A summary of print parameters for Section II experimental set-up.

| | Speed (mm/min) | Pressure (Psi) | Position |
|---|---|---|---|
| First layer - First print | 10 | 3 | 0 |
| First layer - Second print | 10 | 1 | 0 |
| Second to fifth layers | 30 | 3 | 0 |
| Sixth layer | 30 | 4 | 0 |

The Pastes 1 and 3 sintered silver features passed the specification of dye penetration, tape test and microscope delamination inspections. In customer tests, all pastes printed and sintered parts also passed the downstream die attach, wire bond, polymer molding, soldering processes, and device reliability test using this CSI™ packaging method. In other words, Pastes 1 and 3 can both be used for the applications of CSI™ semiconductor packaging processes.

Further comparisons between Pastes 1 and 3 for adhesion between coated stainless steel substrate and sintered silver are shown in Tables 14 and 15 below.

### Section II—Part A Test

In Part A test as shown in Table 14, Mask B, stainless steel coating material sintering at 970° C. and silver sintering at 860° C., first batch S7000-95BC nano silver contained less than 10 ppm calcium is used. The sample size for the adhesion test is 50 DAP and 50 PAD for each type of silver per substrate strip (2 strips are used).

The results indicate that the nano silver Paste 3 PAD shear adhesion increased by approximately 19% and 20% respectively before and after calendaring when compared to non-nano silver samples. The nano silver Paste 3 DAP peel adhesion increased by approximately 14% and 18% respectively before and after calendaring when compared to control non-nano silver paste samples. The control non-nano silver and nano silver S7000-95 samples PAD shear adhesion increased to approximately 100% and 116% respectively after calendaring. The control non-nano silver and nano silver S7000-95 samples DAP peel adhesion change by approximately −6.5% and −6% respectively after calendaring.

TABLE 14
Part A test, control non-nano silver Paste 1 and nano silver Paste 3
silver DAP and silver PAD - adhesion comparison (Mask B, Stainless
Steel Coating Sintering at 970° C. and Silver Sintering at 860° C.).

| | | Sample | | | | |
|---|---|---|---|---|---|---|
| | | Con184- | | Nano silver | Nano silver | |
| | | control | | S7000-95 | S7000-95 | |
| | | (19505) | Avg | (19506) | (19507) | Avg |
| PAD shear | Average | 0.22 | 0.22 | 0.24 | 0.267 | 0.2535 |
| before calendar | from 48 PAD | | | | | |
| | Stdev | 0.01415 | 0.01415 | 0.01785 | 0.02272 | 0.0203 |
| PAD shear | Average | 0.46 | 0.46 | 0.50176 | 0.5681 | 0.5349 |
| after calendar | from 48 PAD | | | | | |
| | Stdev | 0.042 | 0.042 | 0.055 | 0.0558 | 0.0554 |
| % shear increasing by calendar | | — | 100% | — | — | 116% |
| Nano silver % shear increased | | — | — | — | — | 19%, 19.5% |
| before and after calendar | | | | | | |
| compared to control | | | | | | |
| DAP peel | Average | 36.91667 | 36.91667 | 41.25 | 44.67 | 42.96 |
| before calendar | from 8 DAP | | | | | |
| | Stdev | 2.81 | 2.81 | 4.49 | 1.30268 | 2.9 |
| DAP peel after | Average | 34.5 | 34.5 | 39.67 | 41.083 | 40.38 |
| calendar | from 8 DAP | | | | | |
| | Stdev | 2.35 | 2.35 | 2.77 | 1.564 | 2.17 |

| | | | | | |
|---|---|---|---|---|---|
| % peel increased by calendar | — | −6.5% | — | — | −6% |
| Nano silver % peel increased | — | — | — | — | 14%, 18% |
| before and after calendar | | | | | |
| compared to control | | | | | |

### Section II—Part B Test

In Part B test as shown in Table 15, Masks A and B, stainless steel coating material sintering at 970° C. and silver sintering at 860° C., and a second batch of 57000-95BC nano silver containing less than 10 ppm calcium is used. The sample size for the test is 50 DAP and 50 PAD per substrate strip (2 strips are used) for each type of silver pastes. The results showed that with Mask A, the nano silver S7000-95 (lot 2) samples PAD shear adhesion increased by approximately 40%, and the DAP peel adhesion increased by approximately 38% after calendaring when compared to control non-nano silver samples. With Mask B, the nano silver S7000-95 second lot samples PAD shear adhesion increased by approximately 14%, and the DAP peel adhesion increased by approximately 38% after calendar when compared to non-nano silver samples.

TABLE 15
Part B test: Control non-nano silver Paste 1 (second lot) nano silver Paste
3 silver DAP and silver PAD adhesion comparison (Masks A and B, Stainless
Steel Coating Sintering at 970° C. and Silver Sintering at 860° C.).

| | PAD shear after | | DAP peel after | | Nano silver % |
|---|---|---|---|---|---|
| | calendar | | calendar | | peel increase |
| | Average | | Average | | before and after |
| Sample | from 48 PAD | Stdev | from 8 DAP | Stdev | calendar |
| Con184-control | 0.47 | 0.04 | 35.5 | 2.4 | — |
| (19531) Mask A | | | | | |
| Avg | 0.47 | 0.04 | 35.5 | 2.4 | 40%, 38% |
| Nano silver S7000-95 | 0.67 | 0.07 | 50.2 | 4.07 | — |
| (19529) Lot 2, Mask A | | | | | |
| Nano silver S7000-95 | 0.66 | 0.04 | 45 | 3.6 | — |
| (19530) Lot 2, Mask A | | | | | |
| Avg | 0.665 | 0.055 | 47.6 | 3.835 | — |
| Con184-control | 0.3 | 0.02 | 129.3 | 6.4 | — |
| (19515) Mask B | | | | | |
| Avg | 0.3 | 0.02 | 129.3 | 6.4 | 14%, 38% |
| Nano silver S7000-95 | 0.33 | 0.02 | 177.9 | 7.5 | — |
| (19513) Lot 2, MaskB | | | | | |
| Nano silver S7000-95 | 0.35 | 0.02 | 178.9 | 9 | — |
| (19514) Lot 2, MaskB | | | | | |
| Avg | 0.34 | 0.02 | 178.4 | 8.25 | — |

In the Sections I and II tests, the nano silver Pastes 2 and 3 samples show significantly different levels of adhesion improvements for silver DAP peel adhesion, silver PAD shear adhesion when compared to non-nano silver samples depending on mask type, nano silver type and sintering temperature of metal oxide ink that is used for stainless steel substrate coating. It also shows that the nano silver samples obtained significantly different levels of sintered silver to coated stainless steel substrate delamination reduction compared to non-nano silver samples. This occurs both in prototype manual R&D facility in San Jose, Calif. and in the automated high volume manufacturing facility in Penang, Malaysia using many different lots of silver particles and thousands of customers' samples as test vehicles.

The test experiments indicate that Pastes 1, 2 and 3 compositions can all be used for CSI™ semiconductor packaging processes. With nano silver pastes, the adhesion between sintered silver and metal oxide ink coated stainless steel substrate is significantly improved and the interface delamination is also significantly reduced. The usage of nano silver particles will therefore provide the benefit of increasing the yield for the CSI™ packaging process. One skilled in the art should understand that the stainless steel coating material sintering temperature, the wt. % of nano silver used in the past may be adjusted accordingly to maximize the adhesive strength between the sintered silver and coated stainless steel substrate.

Section III: Calcium Effect for the Adhesion Tests for Pastes 1 and 4 (Non-Nano Silver with Low and High Calcium Content), Versus Pastes 1, 2 and 5 (Nano Silver with Low and High Calcium Content)

In this section, Paste 1 with flake SF125 silver particle containing low calcium content (<10 ppm) and Paste 4 with SF125 silver particle containing high calcium content (71 ppm, 76 ppm and 82 ppm) are used. Mask B, stainless steel coating material sintering at 970° C. and silver sintering at 860° C. are used. The sample size for the test was 50 parts for each type of silver.

The experiment detail and set-up are similar to Sections I and II, the DAP peel adhesion evaluation, SEM for interface contact area and SEM EDS calcium mapping of metal are investigated in this experiment.

### Section III—Part A Test

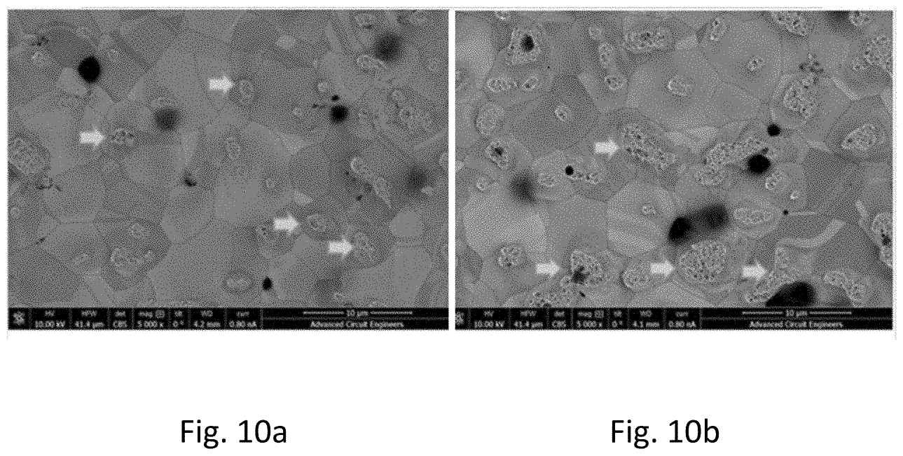

The test results are shown in Table 16 and FIGS. 10-13.

TABLE 16
Low and high calcium content non-nano silver Paste 1 (low calcium) and Paste 4 (high calcium) adhesion study.

| | AG Powder | | | | | | | | | | | |
|---|---|---|---|---|---|---|---|---|---|---|---|---|
| | SF | 728 | 728 | 729 | 729 | 729 | 729 | 728 | 728 | 728 | 728 | 728 |
| | 125C | 53R-00 | 53R-00 | 47R-00 | 47R-0C | 50R-0C | 28R-00 | 75R-00-P | 75R-00-P | 75R-00-P | 75R-00-P | 75R-00-P |
| | Rec. | 23, Apr. | 23, Apr. | 12, May | 21, Aug. | 21, Aug. | 20, Aug. | 20, Aug. | 20, Aug. | 20, Aug. | 20, Aug. | 20, Aug. |
| | Date | 2014 | 2014 | 2015 | 2015 | 2015 | 2015 | 2015 | 2015 | 2015 | 2015 | 2015 |
| PD | D10 | 2.68 | 2.68 | 2.16 | 2.22 | 2.56 | 2.82 | 1.86 | 1.86 | 1.86 | 1.86 | 1.86 |
| | D50 | 4.4 | 4.4 | 3.22 | 3.53 | 4.31 | 4.09 | 3.93 | 3.93 | 3.93 | 3.93 | 3.93 |
| | D90 | 8.91 | 8.91 | 5.39 | 6.21 | 7.33 | 6.58 | 6.39 | 6.39 | 6.39 | 6.39 | 6.39 |
| | D95 | 11.76 | 11.76 | 6.53 | 7.51 | 8.83 | 7.88 | 7.52 | 7.52 | 7.52 | 7.52 | 7.52 |
| SA | M2/g | 0.14 | 0.14 | 0.17 | 0.14 | 0.12 | 0.15 | 0.17 | 0.17 | 0.17 | 0.17 | 0.17 |
| Water | L110 % | 0.02 | 0.02 | 0.04 | 0.03 | 0.04 | 0.03 | 0.03 | 0.03 | 0.03 | 0.03 | 0.03 |
| Oleic | L538C % | 0.45 | 0.45 | 0.35 | 0.53 | 0.51 | 0.20 | 0.39 | 0.39 | 0.39 | 0.39 | 0.39 |
| acid | | | | | | | | | | | | |
| Peel | Max | 98 | 111 | 47 | 27 | 64 | 92 | 90 | 83 | 115 | 127 | 100 |
| data | Avg | 93 | 104 | 42 | 22 | 59 | 84 | 80 | 76 | 89 | 88 | 86 |
| | Min | 87 | 95 | 36 | 15 | 46 | 79 | 72 | 70 | 73 | 70 | 78 |

| | | | | | | | | | | | |
|---|---|---|---|---|---|---|---|---|---|---|---|
| Calcium | <1 ppm | <1 ppm | 71 ppm | 76 ppm | 32 ppm | <1 ppm | <1 ppm | <1 ppm | <1 ppm | <1 ppm | <1 ppm |

The results in Table 16 shows that the high calcium containing SF125 silver lots (72947 and 72950) DAP peel adhesion are only approximately 10-50% that of the low calcium containing SF125 silver lots (72875 and 72853).

SEM and electrostatic spray deposition (ESD) calcium mapping is used to examine the low and high calcium containing silver die attached pad (DAP) contact surface area and morphology between metal oxide ink coated stainless steel layer and sintered silver layer, as well as calcium existence. This is done by peeling the metal oxide ink coated stainless steel substrate off after polymer molding. The SEM pictures 1, 2, 3 and 4 are shown in FIGS. 10-13.

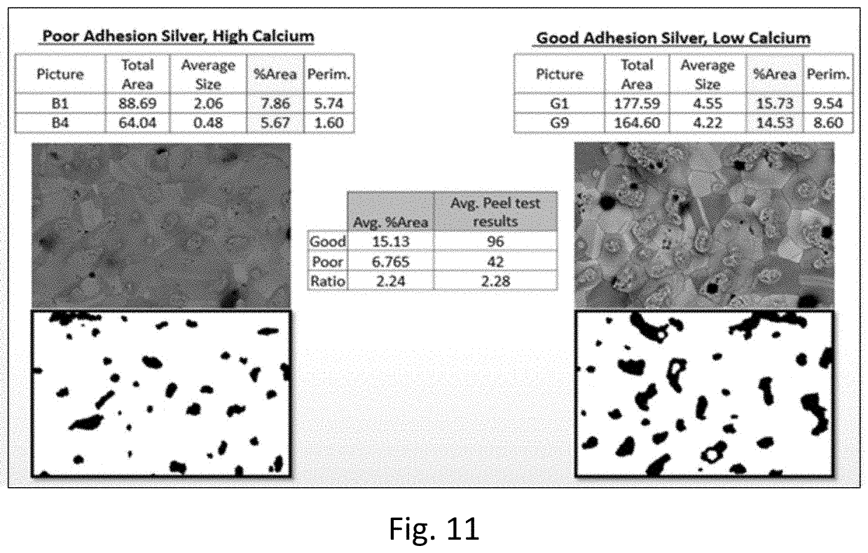

FIG. 10a shows SEM pictures for poor adhesion sample 2 from high calcium content silver powder and FIG. 10b shows SEM pictures for good adhesion sample 2 from low calcium content silver powder, both for sintered silver to substrate peel off surface, while FIG. 11 shows sintered silver and special material contact stainless steel interfaces contact area comparison.

As shown in FIGS. 10a-10b and 11, the good adhesion, low calcium containing SF125 silver samples have larger percentage by area of silver to stainless steel contact surface area as compared to poor adhesion, high calcium containing silver samples. The higher adhesive strength of the pastes may be attributed to a larger contact surface, as shown in FIGS. 10a-10b by the arrows representing a selection of the sintered silver features in the respective conditions and in FIG. 11, the tabulation of the contact area comparison in the respective conditions.

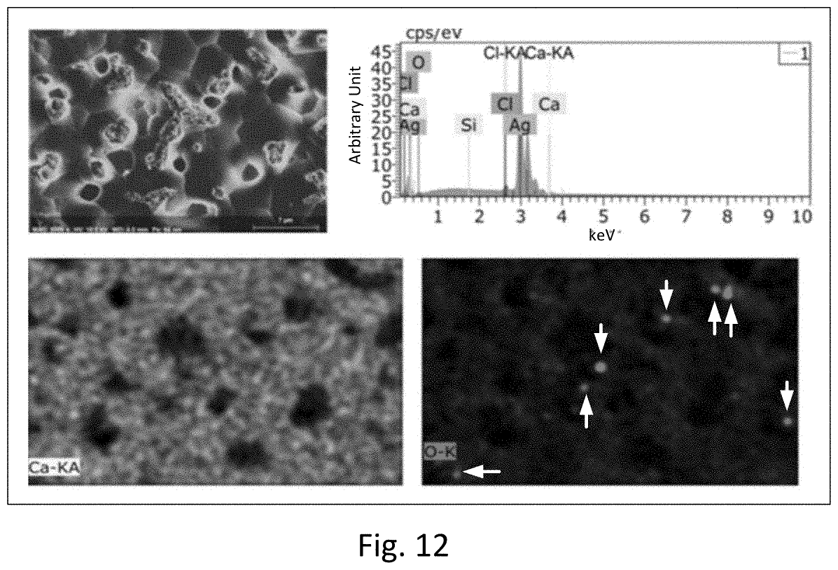

FIG. 12 shows the EDS calcium mapping works with SEM are done to identify calcium in the silver to stainless steel interface attributed to larger contact surface (good against poor). No calcium is observed on the sintered silver/stainless steel substrate surface with good adhesion and low calcium containing SF125 silver samples, while composition of the oxygen functional group is shown as represented by the arrows.

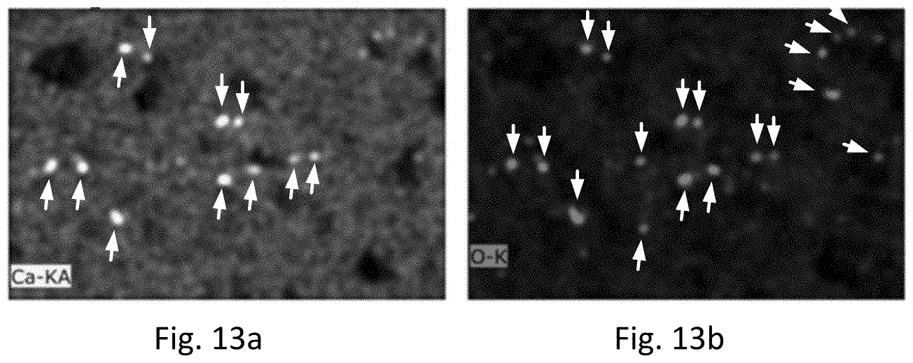

FIG. 13a shows that calcium, as represented by the arrows, appeared on the sintered silver/stainless steel substrate surface with poor adhesion and high calcium containing silver samples, while FIG. 13b shows composition of the oxygen functional group as represented by the arrows.

The results indicate that high calcium content prohibited silver sintering process for silver bonding to metal oxide coated stainless steel in the CSI™ semiconductor packaging processes. The low calcium content (e.g., less than 20 ppm) containing silver paste is therefore most suitable for the application for the CSI™ packaging process.

Section III—Part B Test In this section, Pastes 1 and 2 contain low calcium content, and Paste 5 contains high calcium content (e.g., 820 ppm) are used for testing. Mask B, stainless steel coating material sintering at 970° C. and silver sintering at 860° C. are also used for test. The sample size for the test is 50 PAD and 50 DAP per substrate strip for each type of silver. The experimental set-up is similar to that as described in Sections I and II, the DAP peel adhesion is evaluated in this study.

The results are shown in Table 19 (Test 1) and Table 20 (Test 2). As shown in Table 17, a significant silver to stainless substrate adhesion decrease is observed for high calcium containing nano silver samples when compared to controlled low calcium non-nano silver samples. For example, the PAD Shear adhesion is found to have decreased by approximately 63% and the DAP peel adhesion has decreased by approximately 70%.

TABLE 17
Test 1, high calcium nano silver SB230BC and
low calcium non-nano silver adhesion study.

| | | PAD Shear | | Dap Peel | |
|---|---|---|---|---|---|
| Sample | Pattern | Average | Stdev | Average | Stdev |
| Non-nano silver, low calcium | B | 0.367 | 0.03 | 84 | 5.6 |
| Non-nano silver, low calcium | B | 0.333 | 0.05 | 80 | 6 |
| Non-nano silver, low calcium | B | 0.344 | 0.02 | 76 | 8.8 |
| Non-nano silver, low calcium | B | 0.342 | 0.03 | 83 | 5.9 |
| Non-nano silver, low calcium | B | 0.373 | 0.05 | 72 | 7.5 |
| Avg | — | 0.3518 | 0.012583 | 80.75 | 1.35757136 |
| Nano silver, high calcium | B | 0.147 | 0.01 | 24 | 6.6 |
| Nano silver, high calcium | B | 0.117 | 0.03 | 24 | 8.3 |
| Nano silver, high calcium | B | 0.136 | 0.04 | 23 | 4.8 |
| Nano silver, high calcium | B | 0.131 | 0.02 | 23 | 10.7 |
| Nano silver, high calcium | B | 0.132 | 0.01 | 27 | 3.2 |
| Avg | — | 0.1326 | 0.01291 | 24.2 | 2.93376891 |

As shown in Table 18, a significant silver to stainless steel substrate adhesion decrease is observed for high calcium containing nano silver samples when compared to control low calcium non-nano silver samples. The PAD Shear adhesion decreased by approximately 62%, the DAP peel adhesion decreased by approximately 55%.

TABLE 18
Test 2, high calcium nano silver and low calcium non-nano silver adhesion study.

| | | | PAD Shear | | Dap Peel | |
|---|---|---|---|---|---|---|
| Sample | Pattern | Printer | Average | Stdev | Average | Stdev |
| Control 83, low calcium | B | Milara | 0.367 | 0.03 | 81.06 | 9.3 |
| Control 84, low calcium | B | Milara | 0.333 | 0.05 | 87.5 | 6.5 |
| Avg | — | — | 0.35 | 0.04 | 84.28 | 7.9 |
| Nano 86, high calcium | B | Ekra | 0.15 | 0.03 | 40.1 | 4.3 |
| Nano 87, high calcium | B | Ekra | 0.17 | 0.04 | 33.4 | 4 |
| Nano 90, high calcium | B | Milara | 0.1 | 0.02 | 38.3 | 3.1 |
| Nano 91, high calcium | B | Milara | 0.12 | 0.03 | 43.2 | 4.9 |
| Avg | — | — | 0.135 | 0.03 | 38.3 | 4 |

The results are similar to flake SF125 silver, when calcium content is high, the silver sintering on the metal oxide coated stainless steel is inhibited. The adhesion between the interface is therefore significantly reduced. Low calcium content containing nano silver (e.g., <20 ppm) should therefore be used for the paste formulation for proper bonding strength between the metal oxide ink coated stainless steel and sintered silver.

1. A silver paste composition for screen and/or 3D printing of interconnects of an integrated circuit chip on a metal oxide ink coated stainless steel substrate carrier comprising:
a mixture of two or more distinct range of sizes of electrically conductive silver particles;
a resin in an amount from 0.05 to 10 wt. % of the silver paste composition;
a solvent in an amount from 1 to 25 wt % of the silver paste composition; and
wherein the conductive silver particles are imbedded with a calcium content of less than 20 ppm, and wherein the silver paste composition has a viscosity of 10 to 400 Pa·s at a shear rate of 10 sec⁻¹ at 25° C.

2. The silver paste composition of claim 1, wherein the mixture of two or more distinct range of sizes of electrically conductive silver particles comprises:
a combination of two or more multi-micron-sized silver particles, wherein smaller micron-sized particles are in the range of 3 to 8 μm with a particle size distribution of D50, and bigger micron-sized particles are in the range of 8 to 20 μm with a particle size distribution of D90; and
wherein the wt. ratio of the bigger micron-sized particles to the smaller micron-sized particles is approximately 3:1, and wherein the multi-micron-sized silver particles are greater than 50 wt. % of the silver paste composition.

3. The silver paste composition of claim 1, wherein the mixture of two or more distinct range of sizes of electrically conductive silver particles further comprises:
a combination of two or more multi-micron-sized silver particles, wherein smaller micron-sized particles are in the range of 3 to 8 μm with a particle size distribution of D50, and bigger micron-sized particles are in the range of 8 to 20 μm with a particle size distribution of D90, wherein the wt. ratio of the bigger micron-sized particles to the smaller micron-sized particles is approximately 4:1, and wherein the multi-micron-size silver particles are greater than 50 wt. % of the silver paste composition; and
one or more multi-nano-sized silver particles in the range of 10-150 nm, wherein the wt. ratio between the multi-micron-sized silver particles to the multi-nano-sized silver particle is 34:1, and wherein the multi-nano-sized silver particles are 1-10 wt. % of the silver paste composition.

4. The silver paste composition of claim 1, wherein the metal oxide ink is selected from among nickel oxide, titanium oxide, and calcium oxide.

5. The silver paste composition of claim 1, wherein the electrically conductive silver particles have a shape selected from among cubes, flakes, granules, cylinders, rings, rods, needles, prisms, disks, fibers, pyramids, spheres, spheroids, prolate spheroids, oblate spheroids, ellipsoids, ovoids, and random non-geometric shapes.

6. The silver paste composition of claims 2 and 3, wherein the multi-micron-sized silver particles have a tapped density of 3.6 g/cc or higher and the multi-nano-sized silver particles have a tapped density of 2.4 g/cc or higher.

7. The silver paste composition of claim 1, wherein the resin is selected from among synthetic or natural resins, such as ethyl cellulose resins, rosin ester resins, acrylic resins, bisphenol resin, phenol resin, polyester, acrylic resin, coumarone resin, terpene resin, terpene phenol resin, styrene resin, xylene resin, polyvinyl alcohol, and alkyd resin.

8. The silver paste composition of claim 1, wherein the resin is an ethyl cellulose resin having a molecular weight of 8,000 to 50,000 g/mol.

9. The silver paste composition of claim 1, further comprising a dispersant in an amount of 0.01 to 7 wt. % of the silver paste composition.

10. The silver paste composition of claim 9, wherein the dispersant is selected from among copolymers with acidic groups, such as the BYK® series, including phosphoric acid polyester (DIS PERBYK®111), BYK 9076, BYK 378, alkylolammonium salt of a polymer with acidic groups (DISPERBYK®180), structured acrylic copolymer (DISPERBYK®2008), structured acrylic copolymer with 2-butoxyethanol and 1-methoxy-2 propanol (DISPERBYK®2009), block copolymer with pigment affinic groups (DISPERBYK®2155), polycarboxylate ethers such as these in the Ethacryl series (Lyondell Chemical Company, Houston, Tex. USA), including Ethacryl 1030 and Ethacryl HF series (water-soluble polycarboxylate copolymers) such as Ethacryl M (polyether polycarboxylate sodium salt), Ethacryl 1000, Ethacryl G (water-soluble polycarboxylate copolymers containing polyalkylene oxide polymer), and Solsperser™ hyperdispersant series (Lubrizol, Wickliffe, Ohio USA) including, Solsperse™ 35000, Solsperse™ 32000, Solsperse™ 20000, and Solsperse™ 33000 which are solid polyethylene-imine cores grafted with polyester hyper dispersant.

11. The silver paste composition of claim 1, wherein the solvent is selected from among acetophenone, benzyl alcohol, 2-butoxyethanol, 3-butoxy-butanol, butyl carbitol, y-butyrolactone, 1,2-dibutoxyethane, diethylene glycol monobutyl ether, dimethyl glutarate, dibasic ester mixture of dimethyl glutarate and dimethyl succinate, dipropylene glycol, dipropylene glycol monoethyl ether acetate, dipropylene glycol n-butyl ether, 2-(2-ethoxyethoxy) ethyl acetate, ethylene glycol, 2,4-heptanediol, hexylene glycol, methyl carbitol, N-methyl-pyrrolidone, 2,2,4-trimethyl-1,3-pentanediol di-isobutyrate (TXIB), 2,2,4-trimethyl-1,3-pentanediol monoisobutyrate (texanol), phenoxy ethanol, 1-phenoxy-2-propanol, phenyl carbitol, propylene glycol phenyl ether, terpineol, tetradecane, glycerol, tripropylene glycol n-butyl ether, and mixtures of these solvents.

12. The silver paste composition of claim 1, further comprising an additive selected from among a leveling agent, a defoamer, and a wetting agent or a combination thereof.

13. The silver paste composition of claim 12, wherein the additive is present in an amount of less than 7 wt. % of the silver paste composition.

14. A method of preparing a silver paste composition for screen and/or 3D printing of interconnects of an integrated circuit chip on a metal oxide ink coated stainless steel substrate carrier comprising:
mixing two or more distinct range of sizes of electrically conductive silver particles;
adding a resin in an amount from 0.05 to 10 wt. % of the silver paste composition;
adding a solvent in an amount from 1 to 25 wt % of the silver paste composition;
wherein the conductive silver particles are imbedded with a calcium content of less than 20 ppm, and
wherein the silver paste composition has a viscosity of 10 to 400 Pa·s at a shear rate of 10 sec⁻¹ at 25° C.

15. The method of claim 14, wherein the mixture of two or more distinct range of sizes of electrically conductive silver particles comprises:
a combination of two or more multi-micron-sized silver particles, wherein smaller micron-sized particles are in the range of 3 to 8 μm with a particle size distribution of D50, and bigger micron-sized particles are in the range of 8 to 20 μm with a particle size distribution of D90; and
wherein the wt. ratio of the bigger micron-sized particles to the smaller micron-sized particles is approximately 3:1, and wherein the multi-micron-sized silver particles are greater than 50 wt. % of the silver paste composition.

16. The method of claim 14, wherein the mixture of two or more distinct range of sizes of electrically conductive silver particles further comprises:
a combination of two or more multi-micron-sized silver particles, wherein smaller micron-sized particles are in the range of 3 to 8 μm with a particle size distribution of D50, and bigger micron-sized particles are in the range of 8 to 20 μm with a particle size distribution of D90, and wherein the wt. ratio of the bigger micron-sized particles to the smaller micron-sized particles is approximately 4:1, and wherein the multi-micron-sized silver particles are greater than 50 wt. % of the silver paste composition; and
one or more multi-nano-sized silver particles in the range of 10-150 nm, wherein the wt. ratio between the multi-micron-sized silver particles to the multi-nano-sized silver particle is 34:1, and wherein the multi-nano-sized silver particles are 1-10 wt. % of the silver paste composition.

17. The method of claim 14, wherein the metal oxide ink is selected from among nickel oxide, titanium oxide, and calcium oxide.

18. The method claim 14, wherein the electrically conductive silver particles has a shape selected from among cubes, flakes, granules, cylinders, rings, rods, needles, prisms, disks, fibers, pyramids, spheres, spheroids, prolate spheroids, oblate spheroids, ellipsoids, ovoids, and random non-geometric shapes.

19. The method of claims 15 and 16, wherein the multi-micron-sized silver particles have a tapped density of 3.6 g/cc or higher and the multi-nano-sized silver particles have a tapped density of 2.4 g/cc or higher.

20. The method claim 14, wherein the resin is selected from among synthetic or natural resins, such as ethyl cellulose resins, rosin ester resins, acrylic resins. bisphenol resin, phenol resin, polyester, acrylic resin, coumarone resin, terpene resin, terpene phenol resin, styrene resin, xylene resin, polyvinyl alcohol, and alkyd resin.

21. The method of claim 14, wherein the resin is an ethyl cellulose resin having a molecular weight of 8,000 to 50,000 g/mol.

22. The method of claim 14, further comprising:
adding a dispersant in an amount of 0.01 to 7 wt. % of the silver paste composition.

23. The method of claim 22, wherein the dispersant is selected from among copolymers with acidic groups, such as the BYK® series, including phosphoric acid polyester (DIS PERBYK®111), BYK 9076, BYK 378, alkylolammonium salt of a polymer with acidic groups (DISPERBYK®180), structured acrylic copolymer (DISPERBYK®2008), structured acrylic copolymer with 2-butoxyethanol and 1-methoxy-2 propanol (DISPERBYK®2009), block copolymer with pigment affinic groups (DISPERBYK®2155), polycarboxylate ethers such as these in the Ethacryl series (Lyondell Chemical Company, Houston, Tex. USA), including Ethacryl 1030 and Ethacryl HF series (water-soluble polycarboxylate copolymers) such as Ethacryl M (polyether polycarboxylate sodium salt), Ethacryl 1000, Ethacryl G (water-soluble polycarboxylate copolymers containing polyalkylene oxide polymer), and Solsperser™ hyperdispersant series (Lubrizol, Wickliffe, Ohio USA) including, Solsperse™ 35000, Solsperse™ 32000, Solsperse™ 20000, and Solsperse™ 33000 which are solid polyethylene-imine cores grafted with polyester hyper dispersant.

24. The method of claim 14, wherein the solvent is selected from among acetophenone, benzyl alcohol, 2-butoxyethanol, 3-butoxy-butanol, butyl carbitol, y-butyrolactone, 1,2-dibutoxyethane, diethylene glycol monobutyl ether, dimethyl glutarate, dibasic ester mixture of dimethyl glutarate and dimethyl succinate, dipropylene glycol, dipropylene glycol monoethyl ether acetate, dipropylene glycol n-butyl ether, 2-(2-ethoxyethoxy) ethyl acetate, ethylene glycol, 2,4-heptanediol, hexylene glycol, methyl carbitol, N-methyl-pyrrolidone, 2,2,4-trimethyl-1,3-pentanediol di-isobutyrate (TXIB), 2,2,4-trimethyl-1,3-pentanediol monoisobutyrate (texanol), phenoxy ethanol, l-phenoxy-2-propanol, phenyl carbitol, propylene glycol phenyl ether, terpineol, tetradecane, glycerol, tripropylene glycol n-butyl ether, and mixtures of these solvents.

25. The method of claim 14, further comprising:
adding an additive selected from among a leveling agent, a defoamer, and a wetting agent or a combination thereof.

26. The method of claim 25, wherein the additive is present in an amount of less than 7 wt. % of the silver paste composition.

27. A printed metal oxide coated stainless steel substrate containing a conductive feature formed by the silver paste composition of claims 1-26, wherein the silver paste composition has been screen and/or 3D printed and sintered to remove the solvent and sinter the silver paste composition.
